(19) United States
(12) Patent Application Publication
(10) Pub. No.: US 2025/0373075 A1
(43) Pub. Date: Dec. 4, 2025

(54) MAGNETIC BLOCK STRUCTURES FOR ENHANCED COUPLING COEFFICIENTS IN WIRELESS POWER TRANSFER

(71) Applicant: The University of North Carolina at Charlotte, Charlotte, NC (US)

(72) Inventors: Xiuhu SUN, Chapel Hill, NC (US); Tiefu ZHAO, Charlotte, NC (US); Shen-En CHEN, Charlotte, NC (US); Karl LIN, Charlotte, NC (US); Jiale ZHOU, Charlotte, NC (US); Nicole BRAXTAN, Charlotte, NC (US)

(21) Appl. No.: 19/224,186

(22) Filed: May 30, 2025

Related U.S. Application Data
(60) Provisional application No. 63/654,357, filed on May 31, 2024.

(51) Int. Cl. H02J 50/00; G06F 30/23; H02J 50/10

(52) U.S. Cl. CPC H02J 50/005; G06F 30/23; H02J 50/10

(57) ABSTRACT

A first through last group are defined, each include parameters associated with a magnetic block. A magnetic block coupling coefficient is a function of the parameters. A maximum value of the coupling coefficient is obtained by varying the values of the parameters of one group from their initial values while maintaining the values of the other groups. The maximum value and final values of the varied parameters associated with the one group are stored. Obtaining and storing is repeated for each group. If a difference between the maximum value of the coupling coefficient associated with the last group and the maximum value associated with the first group is greater than a predetermined number, the obtaining and storing is repeated for all groups using the previous final values as initial values. Otherwise, the magnetic block is manufactured according to the final values of each of the parameters associated with all groups.

### CROSS-REFERENCE TO RELATED APPLICATIONS

This application for patent claims priority to and the benefit of Provisional Patent Application No. 63/654,357 entitled Magnetic Block Structures for Enhanced Coupling Coefficients In Wireless Power Transfer filed in the United States Patent and Trademark Office on May 31, 2024, the entire content of which is incorporated herein by reference as if fully set forth below in its entirety and for all applicable purposes.

### GOVERNMENT LICENSE RIGHTS

This invention was made with government support under 693JJ6-21-C-000002 awarded by the United States Department of Transportation. The government has certain rights in the invention.

### TECHNICAL FIELD

This disclosure relates generally to magnetic components, and more specifically, to magnetic block structures that provide enhanced coupling coefficients in wireless power transfer systems, in particular, for inductive power transfer (IPT), and this disclosure still further relates to a finite element analysis (FEA) approach to a configuration of magnetic block structures that exhibit enhanced coupling coefficients in wireless power transfer systems.

### INTRODUCTION

The selection of magnetic components may play a pivotal role in the manufacture of wireless power transfer (WPT) systems and subsystems. Consideration may be given to configurations of the magnetic components, the coils associated with the magnetic components, and the coupling and positioning of the coils with respect to the magnetic components, to name a few. Each of these aspects may affect a coupling coefficient associated with the WPT systems and subsystems.

Conventional manufacturing of the magnetic components may involve the design and fabrication of precise molds that can withstand repeated fillings with powdered ferromagnetic material, high-pressure compaction of the powdered ferromagnetic material into the molds (to solidify the shape of the magnetic component), and high temperature firing and/or sintering to fix the shape of the magnetic component so that the same may be handled and installed into WPT systems without altering its shape. These fixed-shape products may leave little room for modification, for example, to incorporate changes for purposes of experimentation and adjustment of parameters of WPT systems, such as the coupling coefficient, k. Scientists and engineers continue to search for ways to enhance the performance of WPT systems.

### BRIEF SUMMARY OF SOME EXAMPLES

The systems, methods, and devices of this disclosure each have several innovative aspects, no single one of which is solely responsible for the desirable attributes disclosed herein.

In one example, a method of obtaining dimensions of a magnetic block and manufacturing the same is described. The method may include separating a plurality of parameters representative of a plurality of physical attributes of the magnetic block into a plurality of groups, each of the plurality of groups including one or more of the plurality of parameters, each of the plurality of parameters included in only one of the plurality of groups, assigning a respective range, a respective step size, and a respective starting value to each of the plurality of parameters, sequentially obtaining and storing, from a first group to a last group of the plurality of groups, a respective maximum value of a coupling coefficient of the magnetic block and a respective second value (a new value) of each of the plurality of parameters that corresponds to the maximum value of the coupling coefficient, by varying a respective value of each of the plurality of parameters of a respective one of the plurality of groups according to the respective range and the respective step size, while: maintaining the respective second value of the each of the plurality of parameters of each preceding group, and maintaining the respective starting value of the each of the plurality of parameters of each succeeding group, and determining if a difference between the maximum value of the coupling coefficient of the last group of the plurality of groups and the maximum value of the coupling coefficient of the first group of the plurality of groups is less than or equal to a predetermined percentage of the maximum value of the coupling coefficient of the first of the plurality of groups, and if not less than or equal to the predetermined percentage, returning to the sequentially obtaining and storing and the determining using the stored values as the respective starting values, or if less than or equal to the predetermined percentage, manufacturing the magnetic block according to the stored respective second value of each of the plurality of parameters.

In another example, an apparatus is described. The apparatus includes a pair of facing magnetic blocks, a pair of grooves formed through facing surfaces of the pair of facing magnetic blocks, each of the pair of grooves having a groove width and a groove depth, each of the pair of grooves defining a perimeter of an island within outer borders of each of the pair of facing magnetic blocks. In one example, a groove and the island of one of the pair of facing magnetic blocks mirrors that of the other of the pair of facing magnetic blocks; in other examples, one side of the pair may be different from the other side of the pair. The apparatus also includes a pair of coils, each aligned with the pair of grooves, where a first permeability of a space within the pair of grooves is less than a second permeability of a body of a material that comprises the pair of facing magnetic blocks.

In another example, a method is described. The method includes defining a plurality of groups including a first group through a last group, each of the plurality of groups including one or more of a plurality of parameters associated with a magnetic block, a coupling coefficient of the magnetic block being a function of the plurality of parameters, and each of the plurality of parameters included in only one of the plurality of groups. The method includes obtaining a maximum value of the coupling coefficient in response to varying, from an initial value to a final value, the one or more of the plurality of parameters of one of the plurality of groups while maintaining respective values of the one or more of the plurality of parameters of all other groups. The method includes storing the maximum value of the coupling coefficient and the final value of each of the one or more of the plurality of parameters associated with the one of the plurality of groups and repeating, in a group-by-group sequence, the obtaining the maximum value and the storing the maximum value and the final value of each of the one or more of the plurality of parameters associated with the one of the plurality of groups for each of the plurality of groups including the first group through the last group. Thereafter, it is determined if a difference between the maximum value of the coupling coefficient associated with the last group and the maximum value of the coupling coefficient associated with the first group is not less than or equal to a predetermined number (i.e., the difference is greater than the predetermined number), the method returns to the obtaining, the storing, and the repeating that is associated with the first group through the last group, and subsequently returns to the determining. However, if it is determined that the difference between the maximum value of the coupling coefficient associated with the last group and the maximum value of the coupling coefficient associated with the first group is less than or equal to the predetermined number, then the magnetic block is manufactured according to the stored final value of each of the one or more of the plurality of parameters associated with each of the first group through the last group.

An apparatus is disclosed. The apparatus includes one or more memories and one or more processors that are configured to, individually or collectively, based at least in part on information stored in the one or more memories, perform the following process. The apparatus defines a plurality of groups including a first group through a last group, each of the plurality of groups including one or more of a plurality of parameters associated with a magnetic block, a coupling coefficient of the magnetic block being a function of the plurality of parameters, and each of the plurality of parameters included in only one of the plurality of groups. The apparatus obtains a maximum value of the coupling coefficient in response to varying, from an initial value to a final value, the one or more of the plurality of parameters of one of the plurality of groups while maintaining respective values of the one or more of the plurality of parameters of all other groups. The apparatus stores the maximum value of the coupling coefficient and the final value of each of the one or more of the plurality of parameters associated with the one of the plurality of groups. The apparatus repeats, in a group-by-group sequence, the obtaining the maximum value and the storing the maximum value and the final value of each of the one or more of the plurality of parameters associated with the one of the plurality of groups for each of the plurality of groups including the first group through the last group. The apparatus determines if a difference between the maximum value associated with the last group and the maximum value associated with the first group is less than or equal to a predetermined number, and if not less than or equal to the predetermined number, return to the obtain, the store, and the repeat associated with the first group through and including the last group, and subsequently to the determine, or if less than or equal to the predetermined number, manufacture the magnetic block according to the stored final value of each of the one or more of the plurality of parameters associated with each of the first group through the last group.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 is an illustrative example of a two-block magnetic coupler according to some aspects of the disclosure.

FIG. 2 is a magnetic equivalent circuit of the two-block magnetic coupler of FIG. 1 according to some aspects of the disclosure.

FIG. 3 is a graphic representation of a 3D model of a two-block magnetic coupler according to some aspects of the disclosure.

FIG. 4A and FIG. 4B are a YZ cross-section and an XZ cross-section, respectively, of the second magnetic block of the two-block magnetic coupler of FIG. 1 according to some aspects of the disclosure.

FIG. 5 is a method of analyzing a plurality of parameters utilizing finite element analysis (FEA) according to some aspects of the disclosure.

FIG. 6 is a graphic representative of a simulated magnetic flux density (B) in the YZ plane for a first set of magnetic blocks with grooves (right side) and a second set of reference magnetic blocks (left side) according to some aspects of the disclosure.

FIG. 7 is an electrical schematic of a simulated circuit comprising the equivalent lumped components corresponding to a physical example of a pair of magnetic blocks with grooves according to some aspects of the disclosure.

FIG. 8 is a pictographic description of a first process of manufacturing a magnetic block and a reference magnetic block assembly according to some aspects of the disclosure.

FIG. 9 is a pictographic description of a second process of manufacturing a grooved magnetic block and a grooved magnetic block assembly according to some aspects of the disclosure.

FIG. 10 is a block diagram illustrating an example of a hardware implementation of a device employing one or more processing systems according to some aspects of the disclosure.

FIG. 11 is a flow chart illustrating an example process of obtaining the dimensions and location of a groove in a magnetic block and manufacturing the grooved magnetic block in accordance with some aspects of the disclosure.

FIG. 12 is a flow chart illustrating an example process of obtaining the dimensions and location of a groove in a magnetic block and manufacturing the grooved magnetic block in accordance with some aspects of the disclosure.

FIG. 13 is a flow chart illustrating an example process of obtaining the dimensions and location of a groove in a magnetic block and manufacturing the grooved magnetic block in accordance with some aspects of the disclosure.

Like reference numbers and designations in the various drawings indicate like elements.

### DETAILED DESCRIPTION

The detailed description set forth below in connection with the appended drawings is directed to some particular examples for the purpose of describing innovative aspects of this disclosure. However, a person having ordinary skill in the art will readily recognize that the teachings described herein can be applied in a multitude of different ways. Some or all of the examples described may be implemented in any device, system, or network that is capable of wireless power transfer according to one or more technologies or techniques. In some examples, wireless power transfer may involve, for example, the transmission and reception of radio frequency (RF) energy via antenna structures. One example of an antenna structure may include a coil of wire (e.g., a printed trace of metal shaped as a coil of one or more turns or a wire shaped as a coil of one or more turns). The described examples may be implemented, for example, across a broad range of technologies, such as but not limited to consumer electronics, terrestrial and airborne electric vehicles, and any other technology that may implement wireless power transfer to, for example, charge a battery.

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to persons having ordinary skill in the art that these concepts may be practiced without these specific details. In some examples, well-known structures and components are shown in block diagram form in order to avoid obscuring such concepts.

While aspects and examples are described in this application by illustration to some examples, persons having ordinary skill in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of the described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating the described aspects and features may also necessarily include additional components and features for the implementation and practice of claimed and described examples. For example, transmission and reception of wireless signals necessarily includes a number of components for analog and digital purposes (e.g., hardware components including antenna, radio frequency (RF)-chains, power amplifiers, modulators, buffer, processor(s), etc.). It is intended that innovations described herein may be practiced in a wide variety of devices, components, and systems, etc., of varying sizes, shapes, and constitution.

Magnetic components play a pivotal role in enhancing the coupling coefficient within wireless power transfer (WPT) systems. Conventional manufacturing of these magnetic components involves high-pressure compaction and high-temperature sintering, resulting in rigid, fixed-shape products that limit the impact of shape variations on WPT system coupling coefficients. Described herein is the use of finite element analysis (FEA) tools to investigate the influence of different magnetic component shapes on coupling coefficients in planar WPT systems. First, through analyzing the magnetic circuit, a method of setting grooves (e.g., carving, milling, forming) into the magnetic block (MB) is described. Second, a multi-group and narrow-range (MGNR) simulation method is described to identify the critical parameters of the grooves for an enhanced/improved coupling coefficient. Then, reference MBs (without grooves) and grooved MBs are manufactured with magnetic material. The magnetic material may include cement and ferrite particles. Finally, a prototype is constructed to evaluate the performance of the reference MBs and grooved MBs.

The evaluation demonstrated a 7.51% enhancement in the coupling coefficient, k, for the grooved MBs compared to the reference MBs, accompanied by a reduction of 28.24% in magnetic material usage. These findings underscore the effectiveness of this approach in improving the coupling coefficients of WPT systems. Shortcomings of this approach, including minor adverse effects on efficiency, are also described herein.

The various concepts presented throughout this disclosure may be implemented across a broad variety of systems, networks, architectures, and standards. Wireless power transfer (WPT) technology has attracted considerable attention for its potential to eliminate the need for physical connectors in the charging of electronic devices and power supplies. Within this context, magnetic materials, including ferrite materials, have emerged as crucial components, primarily attributed to their high magnetic permeability in guiding and concentrating magnetic field lines. Multiple studies have highlighted the advantages of integrating ferrite materials into WPT systems, resulting in improvements in the coupling coefficient, thus enhancing transmission efficiency and overall system performance in connection with, for example, and without limitation, mobile devices, electric vehicles (EVs), and railway applications.

The volume and shape of ferrite components have been explored. In one example, four different coupler designs were evaluated: (1) an I-type coupler, which may include I-shaped magnetic poles and magnetic plates; (2) a parallel I-type coupler, which may include two I-type ferrite cores adjacent to a rectangular ferrite plate; (3) a U-E-shaped coupler, which may include U-shaped and E-shaped cores; and (4) a W-I-shaped coupler, which may include multiple W-shaped and I-shaped cores. Among these designs, the W-I-shaped coupler stands out for using the least amount of magnetic material (cost saving implied) while still achieving a relatively high power transfer capability. The evaluations of the four different coupler designs may lead to a conclusion that, apart from the volume of the ferrite material used, the structure of the coupler (e.g., the architecture of the magnetic components of a given coupler) also may play a role in influencing the coupling coefficient.

However, in-depth analysis of magnetic components encounters difficulties caused by the inherent limitations associated with some types of magnetic material used (e.g., the ferrite material used). Due to the common practice of high-pressure pressing and high-temperature sintering in the manufacturing process related to magnetic components, the variety of shapes of magnetic components available on the market is perceived as being limited. Furthermore, the hardness of the magnetic materials complicates any attempts at reprocessing. As a result, there is a noticeable need to understand how the precise shape of magnetic components affects the coupling coefficients in WPT systems.

Benefiting from many advantages, magnetic concrete (also known as magnetizable concrete) has garnered increasing interest in the field of WPT. Magnetic concrete may be described as being durable. Magnetic concrete may be readily integrated into various applications. Significantly, magnetic concrete in magnetic block couplers may be used to enhance the coupling coefficient in comparison to compacted and sintered ferromagnetic powders.

Furthermore, magnetic concrete may be versatile, in that it can be poured into molds and made to take on specific shapes (once cured). A process of pouring and curing magnetic concrete in a mold may obviate a process of high-pressure compaction and sintering of dry powdered ferrite material, for example. The moldability of magnetic concrete offers flexibility in the design of mechanical structures. Molds of various shapes may be fabricated. Pouring and curing the magnetic concrete in the variously shaped molds provides a way to study the shape of magnetic components, for example, without the expense of fabricating tools and dies that may be needed to press and form ferrite powder into the same or similar shapes. To address how the shape of magnetic components affects the coupling coefficients, the shapes of magnetic components that exhibit coupling coefficients that have been realized by leveraging the pourable aspect of magnetic concrete in combination with the fabrication of molds of various shapes are described herein. The magnetic components exhibiting enhanced coupling coefficients may be used in various applications, including but not limited to WPT systems.

Factors that may enhance the coupling coefficient in magnetic block couplers are analyzed. Additionally described herein is a use of finite element analysis (FEA) tools that may be utilized to analyze the structure of magnetic components. Additionally described are magnetic blocks (MBs) that are fabricated from magnetic concrete and used to validate the performance of structures described herein.

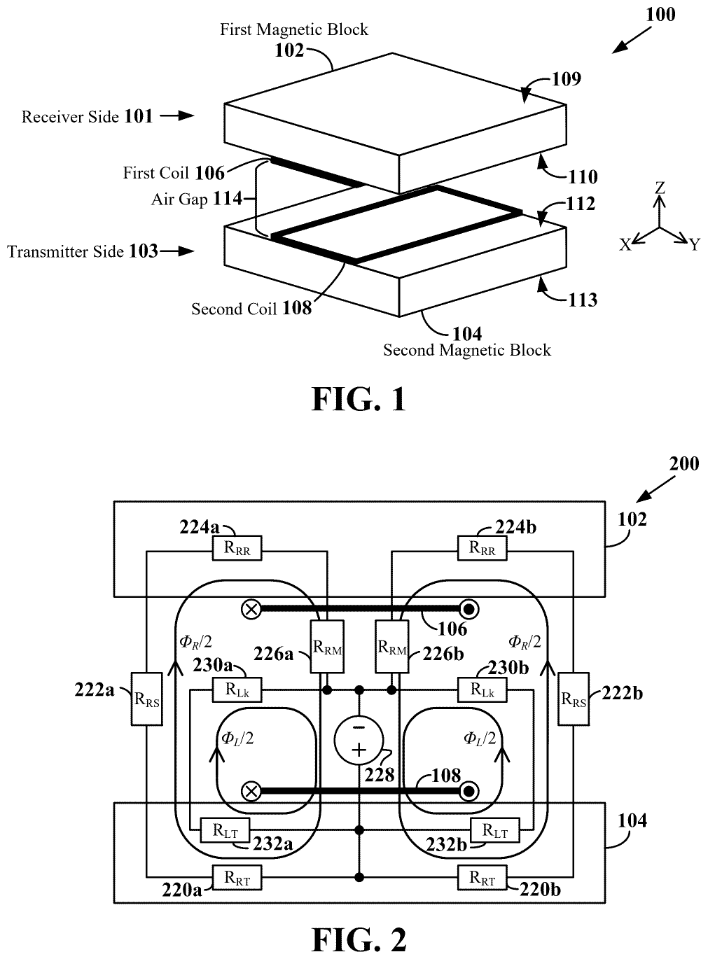

FIG. 1 is an illustrative example of a two-block magnetic coupler 100 according to some aspects of the disclosure. The word “receiver” may be abbreviated as “Rx,” and the word “transmitter” may be abbreviated as “Tx” herein. A receiver side 101 first magnetic block 102 is in a spaced apart configuration above (relative to the Z-axis) a transmitter side 103 second magnetic block 104. The first magnetic block 102 and the second magnetic block 104 may be described as “facing” magnetic blocks. The first magnetic block 102 and the second magnetic block 104 may alternatively be referred to as the receiver side magnetic block and the transmitter side magnetic block, respectively. Each magnetic block has an upper surface and a lower surface (relative to the Z-axis), which are both parallel to an X-Y plane and spaced apart from (and facing) one another. For example, the first magnetic block 102 has a first upper surface 109 and a first lower surface (referred to herein as the lower surface 110), and the second magnetic block 104 has a second upper surface (referred to herein as the upper surface 112) and a second lower surface 113. The lower surface 110 of the first magnetic block 102 faces the upper surface 112 of the second magnetic block 104 as illustrated in FIG. 1. As used herein, the words illustrated and shown may be used interchangeably. The lower surface 110 and the upper surface 112 are spaced apart by an air gap 114. The air gap 114 may be any distance greater than zero.

A receiver coil (referred to herein as the first coil 106) may be coupled to the lower surface 110 of the first magnetic block 102. A transmitter coil (referred to herein as the second coil 108) may be coupled to the upper surface 112 of the second magnetic block 104. The first coil 106 may include a first number of turns of a conductor. The first number of turns may be a whole number (e.g., an integer) or a rational number (e.g., a number with a fractional component) greater than zero. The second coil 108 may include a second number of turns of the conductor. The second number of turns may be a whole number (e.g., an integer) or a rational number (e.g., a number with a fractional component) greater than zero. The first number of turns may be greater than, equal to, or less than the second number of turns. The conductor may be any conductive material, such as copper or gold. In some examples, the conductor may be printed on a given magnetic block (or on a substrate coupled to the given magnetic block). In some examples, the conductor may be a wire or ribbon coupled to the given magnetic block using an adhesive, glue, epoxy, or other bonding agent. In some examples, the conductor may be taped to the given magnetic block using an adhesive tape such as Kapton® polyimide film adhesive tape manufactured by E.I. du Pont de Nemours and Company. In other examples, the conductor may be embedded in a given magnetic block.

The first coil 106 and the second coil 108 are each depicted as a single turn of conductor for ease of illustration and not limitation. Less than one turn and more than one turn are within the scope of the disclosure. The first coil 106 and the second coil 108 are each depicted as having a rectangular perimeter for ease of illustration and not limitation. Other perimeter shapes, such as but not limited to oval and circular, are within the scope of the disclosure.

A coupling coefficient, denoted as k, is a parameter used to describe a coupling between two coils (e.g., between the first coil 106 and the second coil 108), for example, where the coils are configured as a two-block magnetic coupler 100 or as a transformer (not shown). The coupling coefficient, k, is closely related to the transmission capability in a wireless power transfer (WPT) system. The coupling coefficient, k, may be increased by adding (e.g., increasing) magnetic material (e.g., adding by volume, adding by weight) in the vicinity of the two coils. As used herein, the magnetic material may also be referred to as ferromagnetic material. Generally, using more magnetic material may produce a higher coupling coefficient, and using less magnetic material may produce a lower coupling coefficient. However, according to some examples described herein, k may be increased by enhancing the structure (and in actuality removing magnetic material) instead of adding magnetic material. Accordingly, described herein is a use of grooves in the magnetic blocks, which enhance the structure by removing magnetic material by incorporating grooves therein, while obtaining a higher coupling coefficient in association with the grooved magnetic block.

According to some aspects, the coupling coefficient, k, may be improved (i.e., increased), even while the amount of ferromagnetic material included in or making up the magnetic block(s) is reduced. Consequently, at least one benefit of the aspects described herein is the use of less magnetic material while still obtaining a higher coupling coefficient. In the example of FIG. 1, the two-block magnetic coupler 100 (including the first coil 106 and the second coil 108) utilizes the first magnetic block 102 and the second magnetic block 104 to increase the coupling coefficient associated with the two-block magnetic coupler 100 (i.e., increased relative to the coupling coefficient that would be realized without the first magnetic block 102 and the second magnetic block 104). The two-block magnetic coupler 100 may be used in a WPT system, for example. In the example of FIG. 1, both the receiver side 101 and the transmitter side 103 have a respective coil and a respective magnetic block.

FIG. 2 is a magnetic equivalent circuit 200 of the two-block magnetic coupler 100 of FIG. 1 according to some aspects of the disclosure. The magnetic equivalent circuit 200 of the two-block magnetic coupler 100 illustrates a flux received by a receiver ϕ_{R} and a leakage flux ϕ_{L}, which are given by equation (1) and equation (2), respectively, below:

$$\frac{{Φ}_{R}}{2} = \frac{m m f}{{R}_{R T} + {R}_{R S} + {R}_{R R} + {R}_{R M}} \qquad ( 1 )$$

$$\frac{{Φ}_{L}}{2} = \frac{m m f}{{R}_{L K} + {R}_{L T}} \qquad ( 2 )$$

where R_{RT} 220a, 220b, R_{RS} 222a, 222b, R_{RR} 224a, 224b, and R_{RM} 226a, 226b represent the magnetic reluctance of the mutual flux, mmf 228 represents a magnetomotive force, and R_{LK} 230a, 230b and R_{LT} 232a, 232b represent the magnetic reluctance of the leakage flux.

Specifically, R_{RT} 220a, 220b is associated with the second magnetic block 104 (FIG. 1), R_{RR} 224a, 224b is associated with the first magnetic block 102 (FIG. 1), and R_{RS} 222a, 222b and R_{RM} 226a, 226b are associated with the air gap 114 (FIG. 1). R_{LK} 230a, 230b and R_{LT} 232a, 232b represent the magnetic reluctance of the leakage flux. R_{LK} 230a, 230b represents the magnetic reluctance of the leakage flux associated with the air gap 114 (FIG. 1) between the first coil 106 and the second coil 108. R_{LT} 232a, 232b represents the magnetic reluctance of the leakage flux associated with the second magnetic block 104. Mathematically, the coupling coefficient k may be expressed by equation (3), below:

$$k = \frac{{Φ}_{R}}{{Φ}_{R} + {Φ}_{L}} = \frac{1}{\frac{{R}_{R T} + {R}_{R S} + {R}_{R R} + {R}_{R M}}{{R}_{L K} + {R}_{L T}} + 1} \qquad ( 3 )$$

Below, some reference numbers are omitted to improve readability and avoid clutter. For example, R_{RS} 222a and/or R_{RS} 222b may be referred to below as R_{RS}, R_{RM} 226a and/or R_{RM} 226b may be referred to below as R_{RM}.

In equation (3), (R_{RS}+R_{RM}) and R_{LK} may be treated as constants because they are primarily related to the air gap 114 (FIG. 1). The air gap 114 may be stable during static charging. In other words, the lower surface 110 of the first magnetic block 102 and the upper surface 112 of the second magnetic block 104 may maintain a fixed or constant distance of separation (given as the airgap 114) when configured in a WPT system during static charging. Consequently, k may be increased by either decreasing (R_{RT}+R_{RR}) or increasing R_{LT}.

A decrease in (R_{RT}+R_{RR}) may be achieved by increasing the magnetic permeability (e.g., to improve the magnetic permeability) of the magnetic blocks or by increasing (e.g., adding) an amount of magnetic material used in the second magnetic block 104 (FIG. 1), the first magnetic block 102 (FIG. 1), or both the first magnetic block 102 and the second magnetic block 104. In some examples, the amount of magnetic material used in the second magnetic block 104 and the first magnetic block 102 may be equal or substantially equal; however, unequal amounts of magnetic material in the first magnetic block 102 and the second magnetic block 104 are within the scope of the disclosure. However, once the magnetic material is chosen, its permeability remains constant, and increasing (e.g., by adding) magnetic material may escalate costs, rendering a solution that relies on decreasing (R_{RT}+R_{RR}) less than preferred. Accordingly, decreasing (R_{RT}+R_{RR}) is not described further herein. Instead, the methods described herein may provide ways to increase R_{LT} 232a, 232b.

In order to increase R_{LT}, such as the R_{LT} 232a, 232b as shown and described in connection with the magnetic equivalent circuit 200 (FIG. 2) of the two-block magnetic coupler 100 of FIG. 1, magnetic material may be removed from around the first coil 106 (FIGS. 1 and 2) on the first magnetic block 102 (FIGS. 1 and 2), removed from around the second coil 108 (FIGS. 1 and 2) on the second magnetic block 104 (FIGS. 1 and 2) or removed from around both the first coil 106 and the second coil 108 on the first magnetic block 102 and the second magnetic block 104, respectively.

For example, a groove (e.g., a channel, a canal, a trough, a depression) cut from or cut into or otherwise formed at and below a surface of the magnetic material of a magnetic block may be configured in or with the magnetic block. For example, the groove may be included below (e.g., parallel to, coincident with) a coil associated with the magnetic block. By way of example and not limitation, a groove may be defined by the side and bottom walls of the groove that are formed in the magnetic block if the groove is formed with right angles or by a continuous surface of the groove that is formed with a half-circle or U-shaped cross-section in the magnetic block. The interior space of the groove may be devoid of any magnetic material.

Because the permeability of air is lower than the permeability of the magnetic material that forms the body of the magnetic block, the air within a groove (e.g., where magnetic material is absent, where the air has replaced the magnetic material) adjacent to a coil lowers the permeability within the walls of the groove (e.g., compared to the permeability in the absence of the groove, compared to the permeability of the magnetic block in the vicinity of the prospective groove, before the groove was configured in the magnetic block) and subsequently increases a magnetic reluctance. In these examples, the coil may be positioned parallel to an opening of the groove and suspended above, even with, or below a plane that touches the surface of the magnetic block at the opening of the groove (e.g., an imaginary plane lying on the upper surface 112 of the second magnetic block 104 and parallel to the X-Y plane in FIG. 1, or an imaginary plane lying on the lower surface 110 of the first magnetic block 102 and parallel to the X-Y plane in FIG. 1).

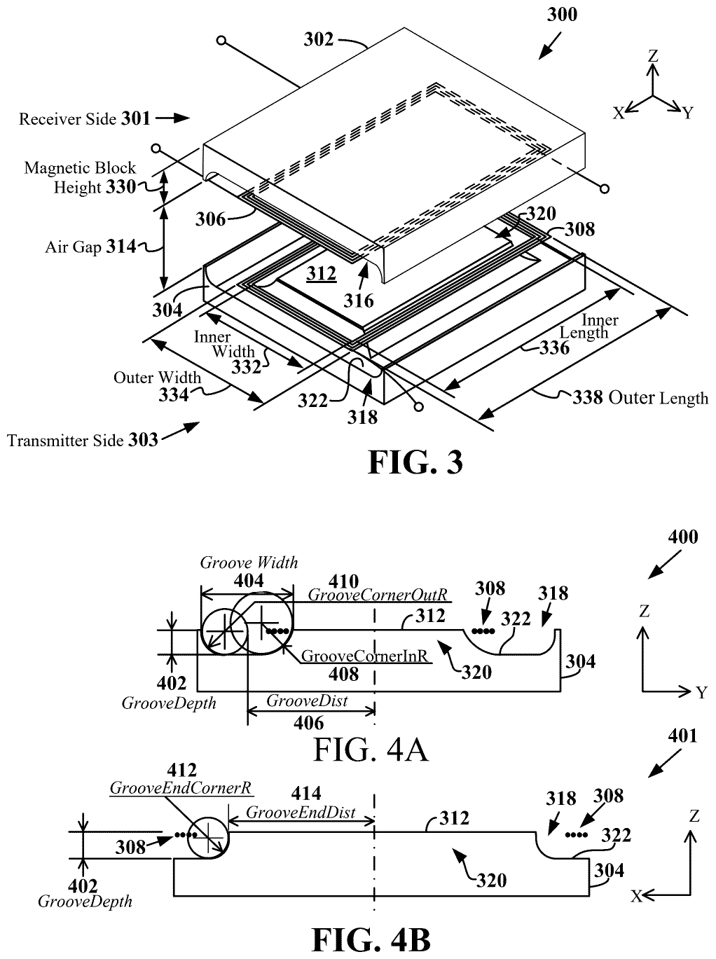

FIG. 3 is a graphic representation of a 3D model of two-block magnetic coupler 300 according to some aspects of the disclosure. A receiver side 301 first magnetic block 302 is in a spaced apart configuration above (relative to the Z-axis) a transmitter side 303 second magnetic block 304, similar to the configuration of the two-block magnetic coupler 100 of FIG. 1. Each magnetic block has an upper surface and a lower surface, which are both parallel to an X-Y plane and spaced apart from one another. The lower surface (hidden from view) of the first magnetic block 302 faces the upper surface 312 of the second magnetic block 304 as illustrated in FIG. 3.

A receiver coil (referred to herein as the first coil 306) may be coupled to the lower surface of the first magnetic block 302. An outline of the first coil 306 is shown in dashed (phantom) lines to illustrate the presence of the first coil 306 on the lower surface of the first magnetic block 302. A transmitter coil (referred to herein as the second coil 308) may be coupled to the upper surface 312 of the second magnetic block 304. A separation distance between the first coil 306 and the second coil is denoted as an air gap 314. A magnetic block height 330 is illustrated in association with the first magnetic block 302 and, because of the symmetry of this example, is the same as the magnetic block height 330 of the second magnetic block 304. The composition, bonding, shape, and number of turns for each coil are the same or similar to those of the two-block magnetic coupler 100 of FIG. 1 and will not be repeated for the sake of brevity. Certain dimensions are illustrated in association with the second coil 308. The dimensions include a coil inner width 332, a coil outer width 334, a coil inner length 336, and a coil outer length 338. The same or similar dimensions may be associated with the first coil 306; however, their illustration is omitted to avoid cluttering the drawing. The dimensions of the first coil 306 and the second coil 308 may be the same or different. The ends (e.g., terminals, nodes) of both the first coil 306 and the second coil 308 are graphically represented using small circles for reference and not limitation.

The first magnetic block 302 includes a first groove 316. The second magnetic block 304 includes a second groove 318. Both the first groove 316 and the second groove 318 may be continuous grooves (e.g., having no beginning and no ending). However, configuring or partitioning either or both of the first groove 316 and the second groove 318 as or into two or more segments (with a wall of magnetic material between lengthwise adjacent segments) is within the scope of the disclosure. The sidewalls of the second groove 318 define an outer edge of a second island 320, whose surface (i.e., the upper surface 312) is perpendicular to the Z-axis and is spaced apart, along the Z-axis, from a bottom surface 322 of the second groove 318. The bottom surface 322 and the upper surface 312 are spaced apart by a groove depth (GrooveDepth 402, FIG. 4).

The dimensions depicted in FIG. 3 are for illustrative and explanatory purposes and are not intended to limit the scope of the disclosure. The 3D model may be referred to as a comprehensive model outline. The rectangular shape of the first coil 306 and the second coil 308, as well as the number of turns depicted, is for ease of illustration and not limitation; any shape and number of turns are within the scope of the disclosure. Additionally, identical magnetic blocks and coils are presented for ease of illustration and not limitation.

FIG. 4A and FIG. 4B are a YZ cross-section 400 and an XZ cross-section 401 (using the XYZ coordinate system presented in FIG. 3), respectively, of the second magnetic block 304 of the two-block magnetic coupler 300 of FIG. 3 according to some aspects of the disclosure. A cross-section of the second coil 308 is depicted as a series of four circles in the XY plane on the opposite sides of the second island 320 in FIG. 4A and FIG. 4B. Also identified for reference in both figures are the upper surface 312 of the second island 320 of the second magnetic block 304, the second groove 318, and the bottom surface 322 of the second groove 318.

One example of experimental parameters of each magnetic block and coil is provided below. For readability, because of the symmetry between the first magnetic block 302 (e.g., the upper block) and the second magnetic block 304 (e.g., the lower block) in the examples of FIG. 3 and FIG. 4, and for ease of illustration and not limitation, a reference to a “magnetic block” is applicable to both the first magnetic block 302 and the second magnetic block 304, and a reference to a “coil” is applicable to both the first coil 306 and the second coil 308.

In the experimental example of FIG. 3 and FIGS. 4A and 4B, the coil had a length of 200 mm and a width of 180 mm, the magnetic block height 330 was 30 mm. The coil employed 7.5 turns of 100/38 Litz wire with a diameter of 1.3208 mm. The coil inner width 332 was 94.5 mm, and the coil outer width 334 was 115 mm. The coil inner length 336 was 117.5 mm, and the coil outer length 338 was 197 mm. The separation distance between the first coil 306 (the receiver side coil) and the second coil (the transmitter side coil), denoted as the air gap 314, was 75 mm. The permeability (μr) of the magnetic block was 19.4. In the experiment, a rectangular shape was defined. In addition, as the magnetic field lines are circular, each groove corner (i.e., an outer groove corner and an inner groove corner) was rounded.

The seven parameters used to define the grooves are shown in FIG. 4A and FIG. 4B. For the grooves along the X-axis direction (perpendicular to the YZ plane of FIG. 4A), which surround the long side of the coil, five parameters were used to define the shape and location of the grooves. GrooveDepth 402 and GrooveWidth 404 were used to determine the depth and width, respectively. GrooveDist 406 was used to define the distance between the center of the groove and the center of the magnetic block. GrooveCornerInR 408 and GrooveCornerOutR 410 were used to determine the inner corner radius and outer corner radius, respectively, within the groove.

For the grooves along the Y-axis direction (also at the end of the block) (perpendicular to the XZ plane in FIG. 4B), two parameters, GrooveEndCornerR 412 and GrooveEndDist 414 were used to define the corner radius and the distance between an end of the groove and the center of the magnetic block, respectively. The Groove Depth 402 for grooves along the X-axis direction is also used to define the depth of the grooves along the Y-axis direction.

A finite element analysis (FEA) method utilizing an electromagnetic field solving program to manipulate physical parameters associated with magnetic blocks and associated coils may find utility in the design of wireless power transfer systems. For example, mechanical parameters of the magnetic blocks may be manipulated, and the effect of the manipulation on electrical parameters, such as but not limited to the coupling coefficient, k, may be observed. One FEA program that may be used to solve electromagnetic field problems may be the Maxwell® program available from Ansys, Inc. of Canonsburg, Pennsylvania. Programs such as, but not limited to, Maxwell® may solve static, frequency-domain, and time-varying magnetic and electric fields.

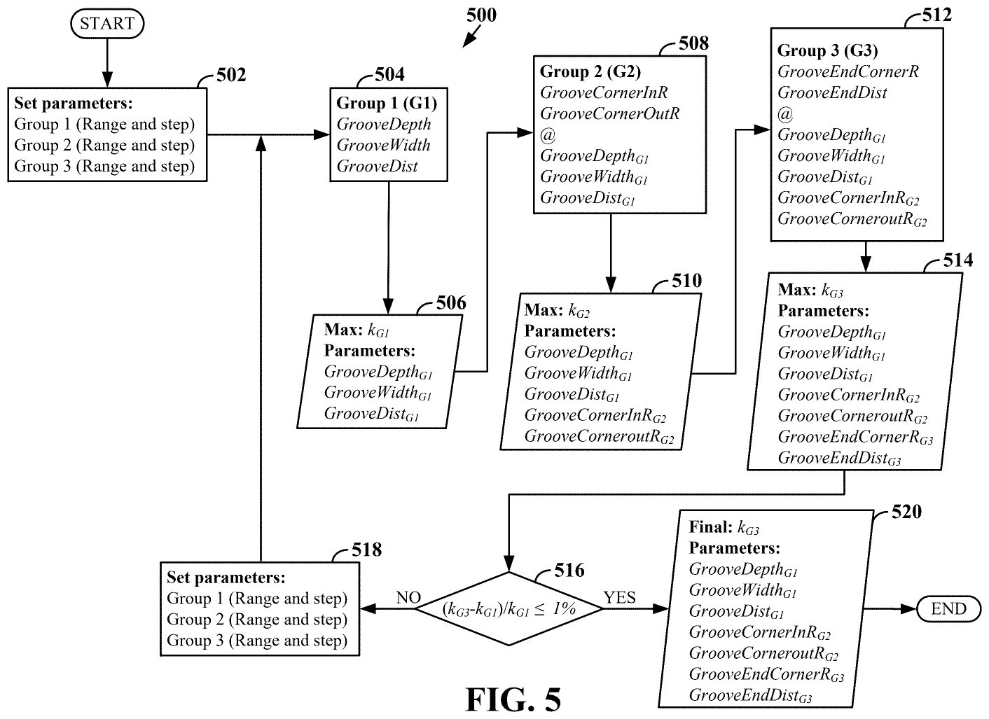

In one example, simulating various parameters may lead to a physical realization of an enhanced coupling coefficient (relative to the coupling coefficient that may be obtained without the benefit of simulations) associated with a magnetic block structure that may be used in association with a wireless power transfer system. However, due to the presence of multiple physical parameters, such as but not limited to the seven groove-related parameters mentioned above, conducting simultaneous simulations for all parameters, even with a limited number of samples per parameter (e.g., five samples per parameter), would result in an extensive total simulation count (5⁷=78125). Such a large number of simulations would significantly prolong the computational time. Therefore, the approach used herein, and illustrated in FIG. 5, may be utilized.

FIG. 5 is a process 500 (e.g., a method) of analyzing a plurality of parameters utilizing finite element analysis (FEA) according to some aspects of the disclosure. The process 500 of FIG. 5 may be referred to as a multi-group narrow-range (MGNR) method herein. MGNR may follow a step-by-step approach to reduce the ranges of multiple variables. At the start, at block 502, parameters may be set. For example, at block 502, the seven parameters may be divided into three groups: Group 1 (G1: GrooveWidth, GrooveDepth, and GrooveDist), Group 2 (G2: GrooveCornerInR and GrooveCornerOutR), and Group 3 (G3: GrooveEndCornerR and GrooveEndDist). Other numbers of groups are within the scope of the disclosure. In this example, three groups are assigned ranges and steps. Then, at block 504, the FEA processing circuitry may simulate these parameters for a first round in the order of G1, G2, and G3. During the simulation of G1 at block 504, the parameters in G2 and G3 are fixed at the minimum values (or starting values). Once the simulation of G1 is finished, at block 506, the maximum k will be recorded as k_{G1}, and the accompanying parameters will be recorded as GrooveDepth_{G1}, Groove Width_{G1}, and GrooveDist_{G1}. Next, the simulation will proceed to block 508 to simulate G2. During the simulation of G2 at block 508, the parameters in G1 remain fixed at GrooveDepth_{G1}, GrooveWidth_{G1}, and GrooveDist_{G1}, and the parameters of G3 remain at their minimum values (or starting values). Once the simulation of G2 is finished, at block 510, a new maximum k will be recorded as k_{G2}, and the accompanying (now improved/enhanced) parameters for G2 will be recorded as GrooveCornerInR_{G2} and GrooveCornerOutR_{G2}. Next, the simulation will proceed to block 512 to simulate G3. During the simulation of G3 at block 512, the parameters in G1 remain fixed (e.g., set) at GrooveDepth_{G1}, GrooveWidth_{G1}, and GrooveDist_{G1}; the parameters in G2 remain fixed (e.g., set) at GrooveCornerInR_{G2} and GrooveCornerOutR_{G2}. Once the simulation of G3 is finished, at block 514, a new (and final) maximum k will be recorded as k_{G3}, and the accompanying (now improved/enhanced) parameters for G3 will be recorded as GrooveEndDist_{G3} and GrooveEndCornerR_{G3}.

So far, the first round is finished, and k_{G1}, k_{G2}, and k_{G3} are obtained. At block 516, the values of k_{G3} and k_{G1} may be used to determine if the process 500 (e.g., including the FEA simulation) needs to be continued. In the present example, at block 516, if the difference between k_{G3} and k_{G1} is less than or equal to a predetermined percentage value (X) of k_{G1} (e.g., X %=1% or 5%) (i.e., (k_{G3}−k_{G1})≤X % of k_{G1}), the FEA simulation will stop, and the process 500 may advance to block 520. At block 520, the final parameters may be recorded as k_{G3}, GrooveWidth_{G1}, GrooveDepth_{G1}, and GrooveDist_{G1} for G1, GrooveCornerInR_{G2} and GrooveCornerOutR_{G2} for G2, and GrooveEndDist_{G3} and GrooveEndCornerR_{G3} for G3. Thereafter, the process 500 may end (e.g., stop).

However, returning to block 516, if at block 516 the difference between k_{G3} and k_{G1} is greater than the predetermined percentage value of k_{G1}, the FEA simulation may continue for another round, and the process 500 may advance to block 518.

For the new round, the aim, once again, is to find a higher k. The FEA may concentrate on the area close to where k_{G3} was obtained (because k_{G3} represents the present maximum value of k obtained by the FEA simulation). Therefore, the parameters may be reset with narrowed ranges and reduced steps. For example, at block 518, the ranges may be narrowed, and the steps may be reduced. Thereafter, the process 500 may return to block 504 and proceed from block 504 through to block 516. That is, in the second round, the process 500 mirrors the previous round: simulate the three groups of parameters in turn. Eventually, the final (maximized) k_{f} and associated parameters will be identified in response to, at block 516, the difference between k_{G3} and k_{G1} being less than or equal to the predetermined percentage value of k_{G1}. Thereafter, the process 500 may proceed to block 520, and following block 520, the process 500 may end.

Consider, for example, the process 500 in which the predetermined percentage value (X) of k_{G1} is 5% of k_{G1}; in this case, the FEA may stop when the difference between k_{G3} and k_{G1} is just lower than 5%. Therefore, the final k_{f} may not be the highest value, and the accompanying parameters may not be the best options, but they are close enough for this example. If an accurate k is needed, more precise simulations can be performed by setting the difference to be less than 5%, for example, 1%. It is noted that reducing the percentage may cause the FEA to take longer, with the tradeoff on time being the obtaining of a higher k.

The simulation results for one example set of magnetic blocks are shown in Table I below:

TABLE I
Dimensional Parameters of Magnetic Blocks

| | | | Reference MBs | |
|---|---|---|---|---|
| Parameter | MBs with Grooves | | (without Grooves) | |
| GrooveWidth | 45.0 | mm | 30.0 | mm |
| GrooveDepth | 12.0 | mm | 2.5 | mm |
| GrooveDist | 65.0 | mm | 52.8 | mm |
| GrooveCornerInR | 20.0 | mm | 0 | mm |
| GrooveCornerOutR | 0 | mm | 0 | mm |
| GrooveEndCornerR | 20.0 | mm | 0 | mm |
| GrooveEndDist | 72.0 | mm | 87.5 | mm |
| self-inductance | 31.14 | μH | 36.20 | μH |
| Coupling Factor (k_{f)} | 0.160 | | 0.1495 | |
| Material Volume | 1.68 × 10⁷ | mm³ | 2.09 × 10⁷ | mm³ |

In other words, a method of obtaining dimensions of a magnetic block and manufacturing the same may include separating a plurality of parameters representative of a plurality of physical attributes of a magnetic block into N groups, where N is a positive nonzero integer. In some examples, N may be greater than or equal to 2. Each of the N groups may include one or more of the plurality of parameters. Each of the plurality of parameters may be included in only one of the N groups. The method may include assigning a range, a step size, and a starting value to each of the parameters. The method may include simulating an electrical performance of the magnetic block by varying parameters of a first of the N groups according to the assigned range and step size while holding other parameters of the other ones of the N groups at their starting values (or their last simulated “final” values), storing the result of a maximum value of a coupling coefficient, k1, and the first parameters associated with the maximum value of k1, sequencing the simulation of the electrical performance of the magnetic block through each of the remaining N−1 groups by sequentially varying the parameters of each of the remaining N−1 groups while holding the parameters of the other groups at either the stored parameters associated a respective maximum value of kN or their starting values. After finishing the simulation of all the N groups of parameters, the method may include determining that the latest value of (kN−k1)/k1 is less than or equal to X % (where X is a whole number that is 0 or greater). However, in response to determining that the latest value of (kN−k1)/k1 is greater than X %, the simulation (e.g., the FEA) may continue to another round, which starts with the stored parameters from the preceding round. A round may end in response to determining that the value of (kN−k1)/k1 is less than or equal to X % (where X is a whole number that is 0 or greater) and storing the latest parameters. Thereafter, the magnetic block may be manufactured according to the latest stored parameters.

Adopting the simulation methodology described above, the parameters for magnetic blocks with grooves were determined and presented in Table I. The simulations for the reference magnetic blocks are also listed. The reference magnetic blocks do incorporate some small grooves (e.g., grooves having a depth substantially equal to the diameter of the wire or wire bundle used to form the coil) to accommodate the coil, but the grooves obtained using the FEA approach described above are distinguishable from the grooves in the reference magnetic blocks.

According to the simulations, the volume of material for the reference magnetic blocks is 2.09×10⁷ mm³, and for the realized magnetic blocks with grooves is 1.68×10⁷ mm³, demonstrating a considerable reduction of 24.40%. Meanwhile, the coupling coefficient, k, exhibits an increase of 10.37%, from 0.1495 to 0.1650. These results verify that the new design has a lighter weight, smaller volume, higher coupling coefficient, and eventually higher material utilization efficiency and better performance.

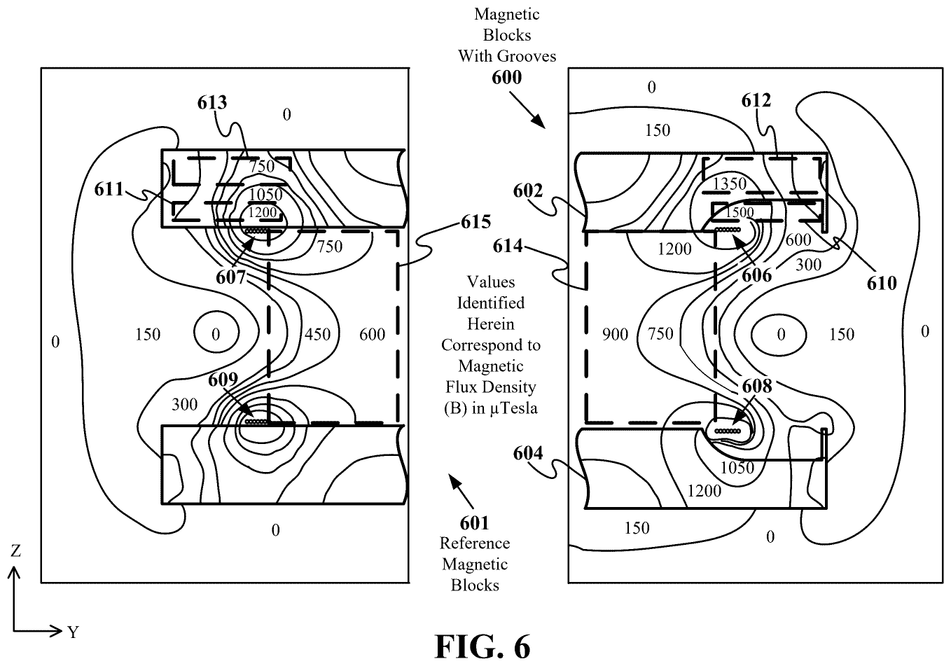

FIG. 6 is a graphic representative of a simulated magnetic flux density (B) in the YZ plane (e.g., in a coordinate system with XYZ axis, such as the coordinate system as shown and referred to in FIG. 3) for a first set of magnetic blocks with grooves 600 (right side) and a second set of reference magnetic blocks 601 (left side) according to some aspects of the disclosure. The first set of magnetic blocks with grooves 600 includes an upper first magnetic block 602, similar to the receiver side 301 first magnetic block 302 as shown and described in connection with FIG. 3. The first set of magnetic blocks with grooves 600 includes a lower second magnetic block 604, similar to the second magnetic block 304 as shown and described in connection with FIGS. 3, 4A, and 4B. The magnetic flux density is presented in the form of a contour map. Various values of the magnetic flux density (B) per contour level are presented in units of μTesla.

The first set of magnetic blocks with grooves 600 includes an upper coil 606 (shown in cross-section) and a lower coil 608 (shown in cross-section), similar to the first coil 306 and second coil 308 as shown and described in connection with FIG. 3. The second set of reference magnetic blocks 601 includes a reference upper coil 607 (shown in cross-section) and a reference lower coil 609. By presenting the simulation results side-by-side, the changes in B can be readily identified.

As illustrated in FIG. 6, the magnetic flux density (B) around the coil (e.g., around the upper coil 606 and the reference upper coil 607, and the lower coil 608 and the reference lower coil 609) is different in the first set of magnetic blocks with grooves 600 compared to the second set of reference magnetic blocks 601. The magnetic flux density (B) decreases in the groove areas (e.g., compare B in first dashed box 610 for the first set of magnetic blocks with grooves 600 to B in a second dashed box 611 for the second set of reference magnetic blocks 601), corresponding to an increase in R_{LT} as per Equation (3), above.

Conversely, the magnetic flux density (B) increases in the far field (e.g., compare B in the third dashed box 612 for the first set of magnetic blocks with grooves 600 to B in the fourth dashed box 613 for the second set of reference magnetic blocks 601), indicating that the grooves force the flux onto a longer path, causing more flux to pass through the opposite coils and resulting in a higher mutual inductance and a corresponding higher value of k.

In other words, as mutual inductance and the coupling coefficient, k, are equivalent, an increase in one corresponds to an increase in the other. Furthermore, in the air gap region (e.g., compare B in the fifth dashed box 614 for the first set of magnetic blocks with grooves 600 to B in the sixth dashed box 615 for the second set of reference magnetic blocks 601), it can be observed that B also increases in the first set of magnetic blocks with grooves 600 compared to the second set of reference magnetic blocks 601, suggesting a greater mutual flux.

A low-power WPT prototype, including magnetic blocks with grooves, was developed to validate the simulation results. The low-power WPT prototype included a WPT system and testing equipment. The magnetic blocks were constructed using ferrite fragments consisting of two sizes of 3C90 ferrite material. The first size ranged from 1.18 to 2.36 mm, and the second size was less than 0.3 mm. Each fragment size contributed 45% of the total weight (i.e., the first size contributed 45% to the total weight, and the second size contributed an additional 45% to the total weight, both contributing, in sum, 90% of the total weight). The remaining 10% of the total weight included cement, which acts as a binding agent. The relative permeability of the magnetic blocks was 19.4, as measured under the International Electrotechnical Commission (IEC) 60404-6 standard (namely, E. IEC, “60404-6:2018 Magnetic Materials—Part 6: Methods of measurement of the magnetic properties of magnetically soft metallic and powder materials at frequencies in the range 20 Hz to 100 kHz by the use of ring specimens,” Magnetic materials-Part, vol. 6, 2018.)

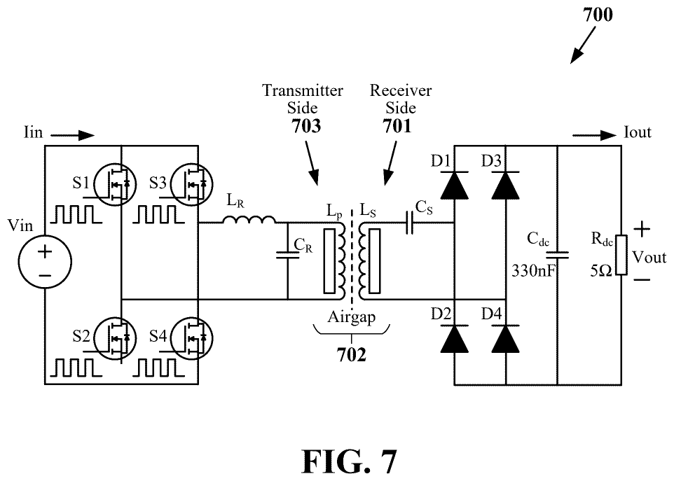

FIG. 7 is an electrical schematic 700 of a simulated circuit comprising the equivalent lumped components corresponding to a physical example of a pair of magnetic blocks with grooves 702 according to some aspects of the disclosure. The electrical schematic 700 illustrates the LCL-compensation topology encompassing both the receiver side 701 and the transmitter side 703 magnetic blocks with grooves 702. A physical test set (not shown) was configured as follows. The transmitter side 703 included a frequency generator (TI TMS320F28379D, not shown but represented by square waves), an inverter (including four C3M0021120D MOSFETs labeled S1-S4), a resonant inductor (LR), a resonant capacitor (CR), and a Tx coil (Lp) with a magnetic block. Three DC sources were utilized: a BK Precision 9116 (available from B&K Precision Corporation) provided input DC voltage (Vin) to the system; an Agilent E3612 (not shown) supplied 12 V DC to the inverter board (not shown); and an Agilent E3630 (not shown) provided 5 V DC to the frequency generator. A first Tektronix MDO3054 oscilloscope (not shown) monitored the voltages and currents on the transmitter side 703.

The receiver side 701 included an Rx coil (Ls) with a magnetic block, a series capacitor (Cs), a rectifier (including four MSC50DC120HJ diodes labeled D1-D4), and an output DC capacitor (Cdc=330 nF). The rectangles associated with the TX coil (Lp) and the Rx coil (Ls) depict the logical positions of the magnetic blocks. A Chrome 63804 electronic load (Rdc) was employed as the load, configured to a resistance of 5 Ω. A second Tektronix MDO3054 oscilloscope (not shown) monitored the voltages and currents on the receiver side 701.

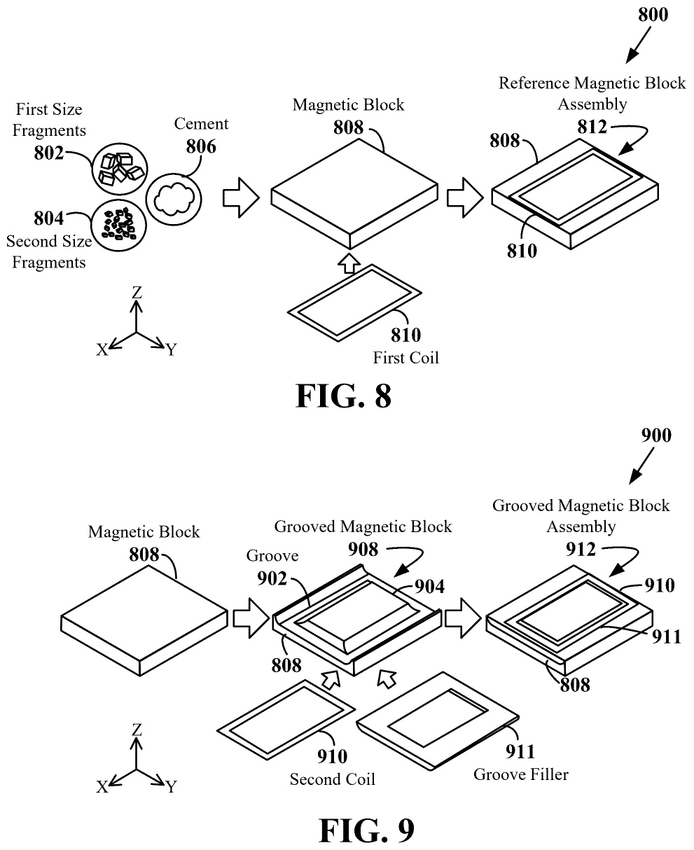

FIG. 8 is a pictographic description of a first process 800 of manufacturing a magnetic block 808 and a reference magnetic block assembly 812 according to some aspects of the disclosure.

FIG. 9 is a pictographic description of a second process 900 of manufacturing a grooved magnetic block 908 and a grooved magnetic block assembly 912 according to some aspects of the disclosure.

When manufacturing magnetic blocks, such as the magnetic block 808, the grooved magnetic block 908, the reference magnetic block assembly 812, and the grooved magnetic block assembly 912, factors such as material density and distribution may influence permeability. To mitigate these effects, the processes of manufacturing depicted in FIGS. 8 and 9 may be employed.

The first process 800 of manufacturing a magnetic block 808 and a reference magnetic block assembly 812 is illustrated in FIG. 8. Initially, two size ranges of ferrite fragments (i.e., fragments of ferrite material), a first size-range of ferrite fragments 802 and a second size-range of ferrite fragments 804 and a cement 806 (e.g., similar to concrete) are thoroughly mixed until a resultant ferromagnetic material admixture (sometimes referred to as magnetic concrete) having a uniform consistency is obtained. One non-limiting example of the ferrite material may be 3C90 ferrite material, manufactured by Ferroxcube International Holding B.V.; other examples of ferrite material are within the scope of the disclosure. One non-limiting example of the size ranges may be a first size range with a particle diameter of 1.18-2.36 mm, and a second size range of less than 0.3 mm; other size ranges with the same or different proportionalities are within the scope of the disclosure. Although one type having two size ranges of ferromagnetic material is shown and described herein, nothing herein is meant to restrict magnetic blocks to one type of ferromagnetic material or two size ranges of any type or types of ferromagnetic material. As used herein, the term “admixture” is meant to describe either a dry mixture or a semiliquid mixture (e.g., a slurry). In the case of a semiliquid mixture, the slurry may be suspended in water or an appropriate solvent or other liquid mixing agent. The ferromagnetic material admixture (dry or wet) (e.g., the magnetic concrete) may be a flowing substance that may be poured into a mold. The ferromagnetic material admixture may be cured in a mold to form the magnetic block 808 with dimensions of 200×180×30 mm, for example.

Next, a first coil 810 may be coupled to the magnetic block 808. The coupling may be achieved using, for example, a bracket (or other mechanical mechanism), an adhesive, a glue, or a tape. In some examples, the first coil 810 coupled to the magnetic block 808 may be sealed (e.g., encased) within a larger conventional concrete (i.e., as opposed to magnetic concrete) or other compound. As used herein, the term “conventional concrete” may refer to a building material made from a mixture of broken stone or gravel, sand, cement, and water, that can be spread or poured into molds and that forms a mass resembling stone after hardening. By way of example, conventional concrete will not impact the coupling coefficient of the first coil 810 coupled to the magnetic block 808. A channel having a depth substantially equal to the diameter of the wire used to form the coil may be formed in the magnetic block 808. The depth of the channel (not shown) may be an order of magnitude or multiple orders of magnitude different from the depth of groove 902 (FIG. 9) as shown and described herein. The channel is not shown to avoid cluttering the drawing. The reference magnetic block assembly 812 may be tested, and the test results may be stored.

The second process 900 for manufacturing the grooved magnetic block 908 and the grooved magnetic block assembly 912 is depicted in FIG. 9. Either a new magnetic block, similar to magnetic block 808, may be manufactured from first size-range of ferrite fragments 802 and second size-range of ferrite fragments 804 of ferromagnetic material and cement 806, or the magnetic block 808 of FIG. 8 may be utilized as a component of the grooved magnetic block assembly 912.

For example, starting with the magnetic block 808 (e.g., after the reference magnetic block assembly 812 (FIG. 8) is tested and the first coil 810 is removed therefrom), a groove 902, or grooves (e.g., forming a continuous or a segmented groove) around a central formation 904 (e.g., an island, a protrusion of magnetic block material extending away from (e.g., in the Z axis direction) and adjacent to a bottom surface of the groove 902) may be formed in the magnetic block 808 as depicted (for exemplary and non-limiting purposes) in FIG. 9. The groove 902 may be formed according to the dimensional parameters described in connection with Table I, above. In one example, the groove 902 was cut into the magnetic block 808 of the reference magnetic block assembly 812.

A groove filler 911, having a shape that conforms to the sidewalls (and floor) of the groove 902, may be fabricated. For example, the groove filler 911 may be printed with a 3D printer. The material used to fabricate the groove filler 911 may be any material with a permeability of 1 (i.e., the permeability of air) or close to 1. In some examples, the groove filler 911 may be 3D printed using a plastic. In some examples, the groove filler 911 may be a polyester or a thermoplastic monomer, such as, for example, polylactic acid (PLA). In some examples, the groove filler 911 may be a paste or other semisolid material that may be spread into the groove 902 and allowed to cure in the groove 902. In some examples, the groove filler 911 may be conventional concrete, wood, or plastic, or any material having a permeability of 1 (i.e., the permeability of air).

In one example, a 3D-printed version of the groove filler 911 was inserted into the groove 902 of the grooved magnetic block 908. The second coil 910 was then coupled to the groove filler 911. The combination of the grooved magnetic block 908, the groove filler 911, and the second coil 910 may be referred to herein as the grooved magnetic block assembly 912.

In one example, for purposes of testing, the grooved magnetic block assembly 912 reuses the magnetic block 808 of the reference magnetic block assembly 812, ensuring that the magnetic permeability between the magnetic block 808 and the grooved magnetic block 908 remains consistent, thereby reducing measurement errors.

It should be pointed out that no water, solvent, or other liquid mixing agent was added during either the first process 800 or the second process 900. As mentioned above, to compare the effect of the two magnetic blocks, the coils, air gap, frequency, and permeability of the material are fixed. However, because the inductance of the coils is changed due to the different magnetic blocks, adjustments, for test purposes, may be implemented for the corresponding resonant inductance L_{R}, resonant capacitance C_{R}, and series capacitance C_{S} (all as shown and described in connection with FIG. 7) within the circuit to ensure a resonance frequency at 85 kHz. The measured parameters for the prototype are listed in Table II below.

By comparing the reference magnetic block assembly 812 and the grooved magnetic block assembly 912, it may be observed that the addition of the groove 902 has resulted in several changes. Among these changes, the self-inductance of the Tx coil and Rx coil decreases from 36.48 uH/36.52 uH to 31.39 uH/31.33 uH, and the mutual inductance M decreases from 5.536 uH to 5.117 uH. However, the coupling coefficient, k, increases from 0.1518 to 0.1632, representing an improvement of 7.51%.

To analyze another aspect, i.e., the utilization of materials, the mass of the magnetic block 808 and the grooved magnetic block 908 was measured. Here, mass is used instead of volume because measuring mass is easier and more accurate than measuring volume. The mass changed from 5832.07 g to 4547.70 g for the two magnetic blocks, reduced by 28.24%, which closely aligns with the simulation. Thus, the design presented herein offers significant possibilities for reducing the cost of magnetic materials.

The two types (i.e., with grooves and without grooves (i.e., reference)) of magnetic blocks were integrated into a prototype for testing. To facilitate comparison, the input power was set to 100 W, and the load was set to 5 Ω. The results measured by the power analyzer are presented in Table II, below:

TABLE II
Experimental Results

| MB Type | Vin(V) | Iin(A) | Pin(W) | Vout(V) | Iout(A) | Pout(W) | η(%) |
|---|---|---|---|---|---|---|---|
| Reference | 150.38 | 0.6694 | 99.96 | 20.63 | 4.1778 | 84.59 | 84.62 |
| W/Grooves | 139.52 | 0.7240 | 100.14 | 20.58 | 4.1484 | 83.54 | 83.42 |

Several conclusions may be drawn from the experimental results. First, under the same input power, the output voltage, Vout, output current, Iout (as shown in FIG. 7), and output power, Pout, only changed slightly, from 20.63 V, 4.1778 A, and 84.59 W for the reference magnetic blocks to 20.58 V, 4.1484 A, and 83.54 W for the grooved magnetic blocks, respectively. Second, the input voltage Vin (139.52 V) for grooved magnetic blocks is 7.78% less than that of the reference magnetic blocks (150.38 V). In other words, with the same input voltage, the grooved magnetic blocks may transmit more energy, thereby increasing the system transmission capacity. This conclusion can be attributed to the increase in the coupling coefficient, k, which is 7.51%. Third, the efficiency reduced from 84.62% to 83.42%, indicating a decrease of 1.44%. The reduced efficiency may be mainly caused by the lower inductance, leading to a lower quality factor Q, increasing the power losses in the coils.

In one example, an apparatus may include a pair of facing magnetic blocks, similar to the magnetic block 808 of FIG. 8, and having a pair of grooves, similar to the groove 902 of FIG. 9, formed in or through the facing surfaces of the pair of facing magnetic blocks. Each of the pairs of magnetic blocks with grooves formed therein may be similar to the grooved magnetic block 908 of FIG. 9.

Each pair of grooves may have a groove width (similar to the GrooveWidth 404 of FIG. 4A) and a groove depth (similar to the GrooveDepth 402 of FIGS. 4A and 4B). Each of the pair of grooves may define a perimeter of an island (similar to the second island 320 as shown and described in connection with FIGS. 3, 4A, and 4B) within outer borders of each of the pair of facing magnetic blocks (e.g., where the island may be a central formation 904 (FIG. 9) or a protrusion of magnetic block material extending away from and adjacent to a bottom surface of the groove 902 (FIG. 9)). In the example, a groove and the island of one of the pair of facing magnetic blocks may mirror that of the other of the pair of facing magnetic blocks. In other examples, the facing magnetic blocks may not mirror one another. The grooves may be different from one another and/or the coils, described next, may be different from one another.

The example may include a pair of coils (e.g., each similar to the second coil 910 of FIG. 9) each aligned with the pair of grooves (e.g., similar to groove 902 of FIG. 9), where a first permeability of a space within the pair of grooves (e.g., within the borders defined by the sidewalls defining the groove width and groove depth) is less than a second permeability of a body of material that comprises the pair of facing magnetic blocks. For example, the permeability of the space within the pair of grooves may be 1 if the grooves are “empty” or “filled” with air.

In one example, a pair of groove fillers (e.g., each similar to the groove filler 911 of FIG. 9) may occupy the groove width and the groove depth of the pair of grooves, each of the pair of groove fillers having a respective one of the pair of coils (e.g., each similar to the second coil 910 of FIG. 9) coupled thereto.

In one example, the permeability of each of the pair of groove fillers may be equal to that of air (i.e., permeability=1).

In one example, the groove width and the groove depth produce a final coupling coefficient that is greater than an initial coupling coefficient obtained with an initial groove width and an initial groove depth. In this example, the initial groove width and the initial groove depth are different, respectively, from the (final) groove width and the (final) groove depth.

Described herein are the application of finite element analysis (FEA) methods in association with designs of magnetic block (MB) structures to enhance wireless power transfer (WPT). The addition of the grooves described herein serves to improve the coupling coefficient and reduce the usage of magnetic material (in comparison to magnetic blocks without these improvements). Simulations demonstrate (within the parameters of the simulations) that this approach may increase the coupling coefficient by about 10.37% and decrease the usage (volume) of magnetic material by about 24.40%. A prototype was developed, which achieved a 7.51% improvement in the coupling coefficient and a 28.24% reduction in the usage (mass) of magnetic material used in comparison to a reference model without the groove.

However, it has also been observed that the DC-DC efficiency decreases by 1.44% due to a reduced quality factor, which may result from the lowered coil self-inductance.

In one example, a method may find an enhanced structure utilizing, for example, finite element analysis in connection with the process 500 as shown and described in connection with FIG. 5.

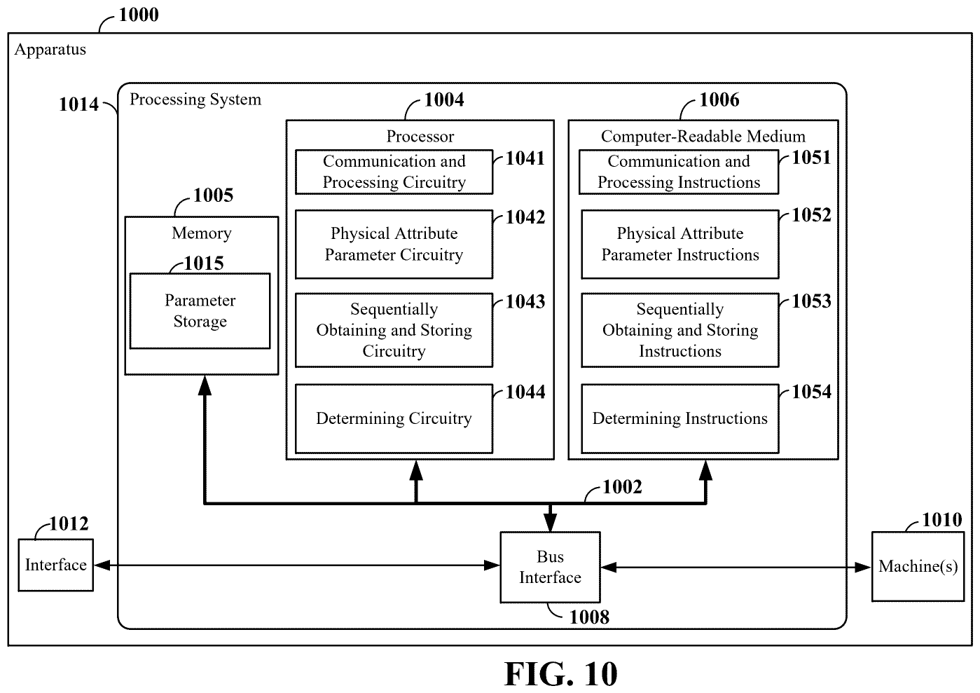

FIG. 10 is a block diagram illustrating an example of a hardware implementation of an apparatus 1000 (e.g., a device, a system) employing one or more processing systems (generally represented by processing system 1014) according to some aspects of the disclosure. The apparatus 1000 may store and execute instructions associated with a finite element analysis process, for example. The apparatus 1000 may store and execute instructions that may be used to drive machines (e.g., multi-axis end mills, shapers, presses, mixers, 3D printers, other computer-aided manufacturing devices or apparatus), for example.

In accordance with various aspects of the disclosure, an element, any portion of an element, or any combination of elements may be implemented with a processing system 1014 that includes one or more processors, generally represented by processor 1004, and one or more memories, generally represented by the memory 1005 and additionally or alternatively generally represented by the computer-readable medium 1006. Examples of processor 1004 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the apparatus 1000 may be configured to perform any one or more of the functions described herein. That is, the one or more processors (generally represented by processor 1004), as utilized in the apparatus 1000, may be configured to, individually or collectively, based at least in part on information stored in the one or more memories (generally represented by the memory 1005 and additionally or alternatively generally represented by the computer-readable medium 1006), implement (e.g., perform) any one or more of the methods or processes shown and described, for example, in FIGS. 1, 2, 3, 4, 5, 8, and/or 9.

In this example, the processing system 1014 may be implemented with a bus architecture, represented generally by the bus 1002. The bus 1002 may include any number of interconnecting buses and bridges, depending on the specific application of the processing system 1014 and the overall design constraints. The bus 1002 communicatively couples together various circuits, including one or more processors (generally represented by the processor 1004), one or more memories (generally represented by the memory 1005), and one or more computer-readable media (generally represented by the computer-readable medium 1006). The bus 1002 may also link various other circuits such as timing sources, peripherals, voltage regulators, and power management circuits, which are well known to persons having ordinary skill in the art and, therefore, will not be described any further.

A bus interface 1008 provides an interface between the bus 1002 and one or more machine(s) 1010 (e.g., multi-axis end mills, shapers, presses, mixers, 3D printers, other computer-aided manufacturing devices or apparatus), for example. The machine(s) 1010 may provide a means for manufacturing a magnetic block that may include a groove(s), such as those shown and described herein. The bus interface 1008 may also provide an interface between the bus 1002 and a user interface 1012 (e.g., keypad, display, touch screen, speaker, microphone, control features, sound and/or light warning/alert/feedback devices, etc.). Of course, the user interface 1012 is optional and may be omitted in some examples.

One or more processors, represented individually and collectively by processor 1004, may be responsible for managing the bus 1002 and general processing, including the execution of software stored on the computer-readable medium 1006. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on the computer-readable medium 1006. The software, when executed by the processor 1004, causes the processing system 1014 to perform the various processes and functions described herein for any particular apparatus.

The computer-readable medium 1006 may be a non-transitory computer-readable medium and may be referred to as a computer-readable storage medium or a non-transitory computer-readable medium. The non-transitory computer-readable medium may store computer-executable code (e.g., processor-executable code). The computer executable code may include code for causing the apparatus 1000 (e.g., including a computer, one or more processors) to implement one or more of the functions described herein. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium 1006 may reside in the processing system 1014, external to the processing system 1014, or distributed across multiple entities, including the processing system 1014. The computer-readable medium 1006 may be embodied in a computer program product or an article of manufacture. For example, a computer program product or article of manufacture may include a computer-readable medium in packaging materials. In some examples, the computer-readable medium 1006 may be part of the memory 1005. Persons having ordinary skill in the art will recognize how best to implement the described functionality presented throughout this disclosure, depending on the particular application and the overall design constraints imposed on the overall system. The computer-readable medium 1006 and/or the memory 1005 may also be used for storing data that is manipulated by the processor 1004 when executing software.

In some aspects of the disclosure, the processor 1004 may include communication and processing circuitry 1041 configured for various functions, including, for example, communicating with a user via the user interface 1012 and/or the machine(s) 1010. In some examples, the communication and processing circuitry 1041 may include one or more hardware components that provide the physical structure that performs processes related to communication (e.g., signal reception and/or signal transmission) and signal processing (e.g., processing a received signal and/or processing a signal for transmission). In some examples, the communication and processing circuitry 1041 may include one or more hardware components that provide the physical structure that performs processes related to assigning a respective range, a respective step size, and a respective starting value to each of the plurality of parameters. The communication and processing circuitry 1041 may include one or more hardware components that provide the physical structure that performs processes related to repeating, in a group-by-group sequence, the obtaining the maximum value of the coupling coefficient and the storing the maximum value of the coupling coefficient and the final value of each of the one or more of the plurality of parameters associated with the one of the plurality of groups for each of the plurality of groups including the first group through the last group. The communication and processing circuitry 1041 may further be configured to execute communication and processing instructions 1051 (e.g., software) stored, for example, on the computer-readable medium 1006 to implement one or more functions described herein.

In some aspects of the disclosure, the processor 1004 may include physical attribute parameter circuitry 1042 configured for various functions, including, for example, separating a plurality of parameters representative of a plurality of physical attributes of the magnetic block into a plurality of groups, each of the plurality of groups including one or more of the plurality of parameters, each of the plurality of parameters included in only one of the plurality of groups. In some examples, the physical attribute parameter circuitry 1042 may include one or more hardware components that provide the physical structure that performs processes related to defining a plurality of groups including a first group through a last group, each of the plurality of groups including one or more of a plurality of parameters associated with the magnetic block, a coupling coefficient of the magnetic block being a function of the plurality of parameters, and each of the plurality of parameters included in only one of the plurality of groups. The physical attribute parameter circuitry 1042 may further be configured to execute physical attribute parameter instructions 1052 (e.g., software) stored, for example, on the computer-readable medium 1006 to implement one or more functions described herein.

In some aspects of the disclosure, the processor 1004 may include sequentially obtaining and storing circuitry 1043 configured for various functions, including, for example, sequentially obtaining and storing, from a first group to a last group of the plurality of groups, a respective maximum value of a coupling coefficient of the magnetic block and a respective second value of each of the plurality of parameters that corresponds to the maximum value of the coupling coefficient, by varying a respective value of each of the plurality of parameters of a respective one of the plurality of groups according to the respective range and the respective step size, while: maintaining the respective second value of the each of the plurality of parameters of each preceding group, and maintaining the respective starting value of the each of the plurality of parameters of each succeeding group. In some examples, the sequentially obtaining and storing circuitry 1043 may be configured for various functions, including, for example, obtaining a maximum value of the coupling coefficient in response to varying, from an initial value to a final value, the one or more of the plurality of parameters of one of the plurality of groups while maintaining respective values of the one or more of the plurality of parameters of all other groups, and storing the maximum value of the coupling coefficient and the final value of each of the one or more of the plurality of parameters associated with the one of the plurality of groups. The sequentially obtaining and storing circuitry 1043 may further be configured to execute sequentially obtaining and storing instructions 1053 (e.g., software) stored, for example, on the computer-readable medium 1006 to implement one or more functions described herein.

In some aspects of the disclosure, the processor 1004 may include determining circuitry 1044 configured for various functions, including, for example, determining if a difference between the maximum value of the coupling coefficient of the last group of the plurality of groups and the maximum value of the coupling coefficient of the first group of the plurality of groups is less than or equal to a predetermined percentage of the maximum value of the coupling coefficient of the first of the plurality of groups, and if not less than or equal to the predetermined percentage, returning to the sequentially obtaining and storing and the determining using the stored values as the respective starting values, or if less than or equal to the predetermined percentage, manufacturing the magnetic block according to the stored (e.g., stored in parameter storage 1015 of memory 1005) respective second value of each of the plurality of parameters. In other examples, the determining circuitry 1044 configured for various functions, including, for example, determining if a difference between the maximum value of the coupling coefficient associated with the last group and the maximum value of the coupling coefficient associated with the first group is less than or equal to a predetermined number, and if not less than or equal to the predetermined number, returning to the obtaining, the storing, and the repeating associated with the first group through the last group, and subsequently to the determining, or if less than or equal to the predetermined number, manufacturing the magnetic block according to the stored final value of each of the one or more of the plurality of parameters associated with each of the first group through the last group. In some examples, the predetermined number is a predetermined percentage of the maximum value of the coupling coefficient associated with the first group. The determining circuitry 1044 may further be configured to execute determining instructions 1054 (e.g., software) stored, for example, on the computer-readable medium 1006 to implement one or more functions described herein.

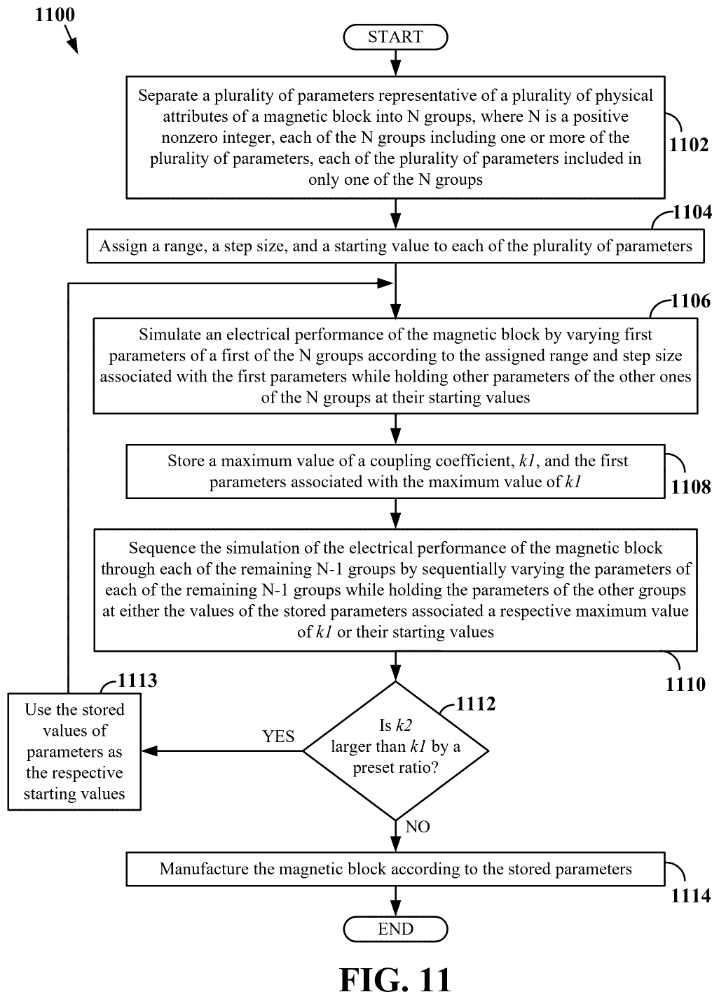

FIG. 11 is a flow chart illustrating an example process 1100 (e.g., a method) of obtaining the dimensions and location of a groove in a magnetic block and manufacturing the grooved magnetic block in accordance with some aspects of the disclosure. The dimensions and location may be examples of a plurality of physical attributes that may be represented by one or more of a plurality of parameters associated with the magnetic block. As described below, some or all illustrated features may be omitted in a particular implementation within the scope of the present disclosure, and some illustrated features may not be required for implementation of all embodiments. In some examples, the process 1100 may be carried out by the apparatus 1000 or more specifically by the processor 1004 of the apparatus 1000 as shown and described in connection with FIG. 10. In some examples, various circuits of the apparatus 1000 may provide the means to perform the processes shown and described, for example, with respect to blocks 1102-1114 of FIG. 11. In some examples, the process 1100 may be carried out by any suitable apparatus or means for carrying out the functions or algorithm described below.

At block 1102, a processor may separate a plurality of parameters representative of a plurality of physical attributes of a magnetic block into N groups, where N is a positive nonzero integer, each of the N groups including one or more of the plurality of parameters, each of the plurality of parameters included in only one of the N groups. In some examples, the plurality of parameters representative of the plurality of physical attributes of the magnetic block may include, but are not limited to, at least one of: a groove width (Groove Width), a groove depth (GrooveDepth), a groove distance (GrooveDist), a groove corner inside radius (GrooveCornerInR), a groove corner outside radius (GrooveCornerOutR), a groove end corner radius (GrooveEndCornerR), or a groove end distance (GrooveEndDist). In some examples, parameters in addition to the plurality of parameters representative of the plurality of physical attributes of the magnetic block may further, or may alternatively, include at least one of: self-inductance, coupling factor, or material volume.

At block 1104, the processor may assign a range, a step size, and a starting value to each of the plurality of parameters.

At block 1106, the processor may simulate an electrical performance of the magnetic block by varying first parameters of a first of the N groups according to the assigned range and step size associated with each of the first parameters while holding other parameters of the other ones of the N groups at their starting values.

At block 1108, the processor may store a maximum value of a coupling coefficient, k1, and the first parameters associated with the maximum value of k1.

At block 1110, the processor may sequence the simulation of the electrical performance of the magnetic block through each of the remaining N−1 groups by sequentially varying the parameters of each of the remaining N−1 groups while holding the parameters of the other groups at either the values of the stored parameters associated with a respective maximum value of k2 or their starting values.

At block 1112, the processor may determine if the latest value of k2 is larger than k1 by a preset ratio. It is noted that k2 is expected to be greater than or equal to k1 because the simulation is to find a higher k. If k2 is equal to k1, there is no room for improvement and the simulation will end; if k2 is much larger than k1, there is still room for improvement and the simulation will continue. Accordingly, at block 1112, if the processor determines that k2 is larger than k1 by a preset ratio,, the process may advance to block 1113, where the processor will use the stored values of various parameters as the respective starting values of those parameters. Thereafter, the process will return to block 1106 and repeat the process, such that the repeated process utilizes the stored values as the starting values, and the repeated process may increase the value of k to be greater than or equal to a new maximum value of k. However, if the processor determines that k2 is not larger than k1 by the preset ratio,, then the process 1100 may continue to block 1114. In another example, instead of determining if the latest value of k is greater than or equal to the maximum value of k, the processor may determine if the latest value of k minus a (previously stored) initial value of k is less than or equal to a predetermined percentage of the initial value of k. That is, the processor may determine if the difference between the latest value of k and the initial value of k is less than or equal to a predetermined percentage of the initial value of k.

At block 1114, the processor may manufacture the magnetic block according to the stored parameters; for example, the processor may cause a machine, such as an end mill, or a milling machine, to form a groove in the magnetic block that is dimensioned according to the plurality of parameters stored in a memory associated with the processor.

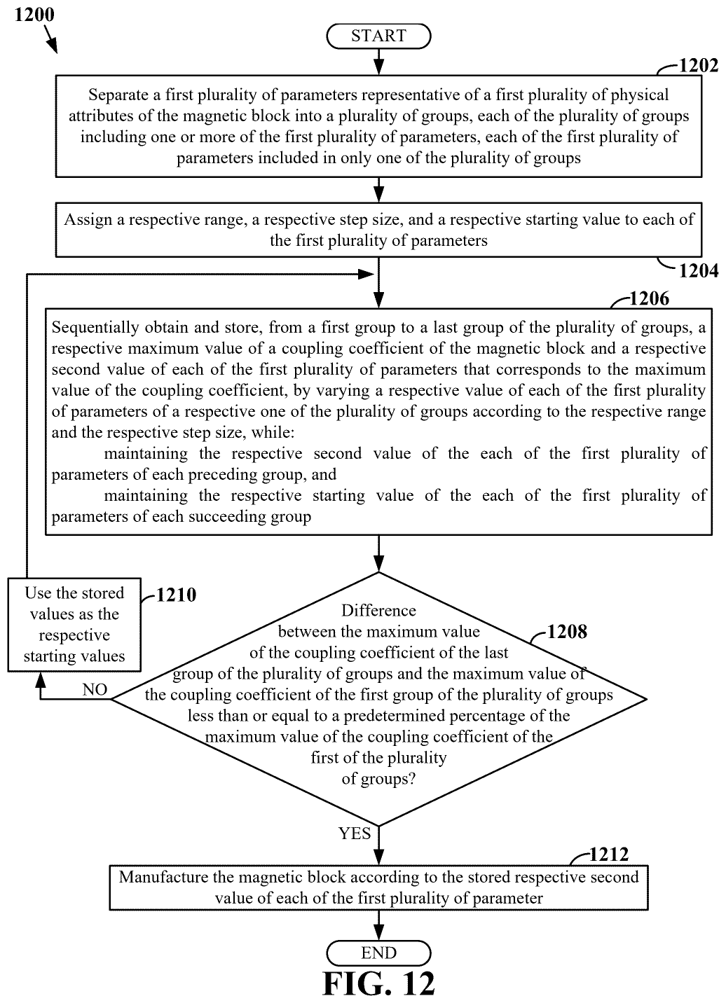

FIG. 12 is a flow chart illustrating an example process 1200 (e.g., a method) of obtaining the dimensions and location of a groove in a magnetic block and manufacturing the grooved magnetic block in accordance with some aspects of the disclosure. The dimensions and location may be examples of a plurality of physical attributes that may be represented by one or more of a plurality of parameters associated with the magnetic block. As described below, some or all illustrated features may be omitted in a particular implementation within the scope of the present disclosure, and some illustrated features may not be required for implementation of all embodiments. In some examples, the process 1200 may be carried out by the apparatus 1000 or more specifically by the processor 1004 of the apparatus 1000 as shown and described in connection with FIG. 10. In some examples, various circuits of the apparatus 1000 may provide the means to perform the processes shown and described, for example, with respect to blocks 1202-1212 of FIG. 12. In some examples, the process 1200 may be carried out by any suitable apparatus or means for carrying out the functions or algorithm described below.

At block 1202, a processor may separate a plurality of parameters representative of a plurality of physical attributes of the magnetic block into a plurality of groups, each of the plurality of groups including one or more of the plurality of parameters, each of the plurality of parameters included in only one of the plurality of groups. In some examples, the plurality of parameters representative of the plurality of physical attributes of the magnetic block may include, but are not limited to, at least one of: a groove width (GrooveWidth), a groove depth (GrooveDepth), a groove distance (GrooveDist), a groove corner inside radius (GrooveCornerInR), a groove corner outside radius (GrooveCornerOutR), a groove end corner radius (GrooveEndCornerR), or a groove end distance (GrooveEndDist). In some examples, parameters in addition to or as an alternative to the plurality of parameters representative of the plurality of physical attributes of the magnetic block may further, or may alternatively, include at least one of: self-inductance, coupling factor, or material volume.

At block 1204, the processor may assign a respective range, a respective step size, and a respective starting value to each of the plurality of parameters.

At block 1206, the processor may sequentially obtain and store, from a first group to a last group of the plurality of groups, a respective maximum value of a coupling coefficient of the magnetic block and a respective second value of each of the plurality of parameters that corresponds to the maximum value of the coupling coefficient, by varying a respective value of each of the plurality of parameters of a respective one of the plurality of groups according to the respective range and the respective step size, while: maintaining the respective second value of the each of the plurality of parameters of each preceding group, and maintaining the respective starting value of the each of the plurality of parameters of each succeeding group.

At block 1208, the processor may determine if a difference between the maximum value of the coupling coefficient of the last group of the plurality of groups and the maximum value of the coupling coefficient of the first group of the plurality of groups is less than or equal to a predetermined percentage of the maximum value of the coupling coefficient of the first of the plurality of groups, and

In response to the difference being not less than or equal to the predetermined percentage of the maximum value of the coupling coefficient of the first of the plurality of groups, the processor may advance to block 1210. At block 1210, the processor may use the stored values as the respective starting values and then return to block 1206.

In response to the difference being less than or equal to the predetermined percentage of the maximum value of the coupling coefficient of the first of the plurality of groups, the processor may advance to block 1212 and may cause the magnetic block to be manufactured according to the stored respective second value of each of the plurality of parameters.

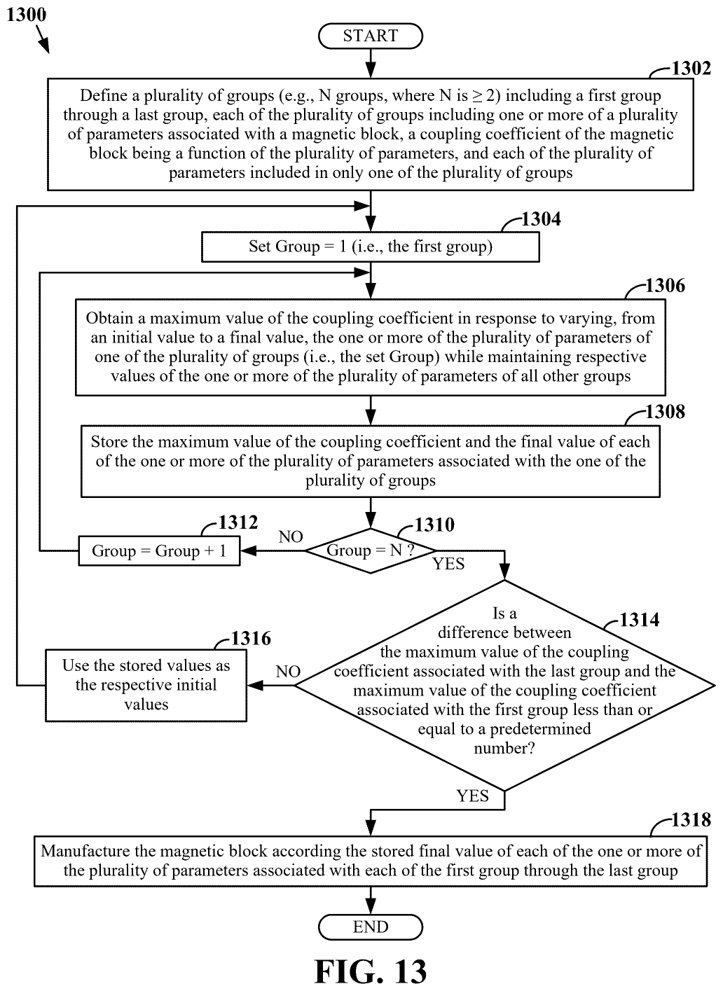

FIG. 13 is a flow chart illustrating an example process 1300 (e.g., a method) of obtaining the dimensions and location of a groove in a magnetic block and manufacturing the grooved magnetic block in accordance with some aspects of the disclosure. The dimensions and location may be examples of a plurality of physical attributes that may be represented by one or more of a plurality of parameters associated with the magnetic block. As described below, some or all illustrated features may be omitted in a particular implementation within the scope of the present disclosure, and some illustrated features may not be required for implementation of all embodiments. In some examples, the process 1300 may be carried out by the apparatus 1000 or more specifically by the processor 1004 of the apparatus 1000 as shown and described in connection with FIG. 10. In some examples, various circuits of the apparatus 1000 may provide the means to perform the processes shown and described, for example, with respect to blocks 1302-1318 of FIG. 13. In some examples, the process 1200 may be carried out by any suitable apparatus or means for carrying out the functions or algorithm described below.

At block 1302, the processor may define a plurality of groups (e.g., N groups, where N is ≥2) including a first group (e.g., Group 1 (G1)) through a last group (e.g., Group N (GN)), each of the plurality of groups including one or more of a plurality of parameters associated with a magnetic block, a coupling coefficient of the magnetic block being a function of the plurality of parameters., Each of the plurality of parameters may be included in only one of the plurality of groups (e.g., all as shown and described in connection with FIG. 5). For example, the physical attribute parameter circuitry 1042, as shown and described in connection with FIG. 10, may provide a means for defining a plurality of groups including a first group through a last group, each of the plurality of groups including one or more of a plurality of parameters associated with a magnetic block, a coupling coefficient of the magnetic block being a function of the plurality of parameters, and each of the plurality of parameters included in only one of the plurality of groups.

In some examples, defining the plurality of groups may include separating a plurality of parameters representative of a plurality of physical attributes of the magnetic block into the plurality of groups. In some examples, the plurality of parameters representative of the plurality of physical attributes of the magnetic block may include at least one of: a groove width (GrooveWidth), a groove depth (GrooveDepth), a groove distance (GrooveDist), a groove corner inside radius (GrooveCornerInR), a groove corner outside radius (GrooveCornerOutR), a groove end corner radius (GrooveEndCornerR), or a groove end distance (GrooveEndDist). Other parameters in addition to the plurality of parameters representative of the plurality of physical attributes of the magnetic block may further include at least one of: self-inductance, coupling factor, or material volume.

At block 1304, the processor may set a counter to a value equal to 1. For example, the counter may be named “Group” and the first group exercised by the processor may be Group 1 (G1). Accordingly, in the example of block 1304, the processor may set Group to a value of 1. For example, the communications and processing circuitry 1041, as shown and described in connection with FIG. 10, may provide a means for setting a counter to a value equal to 1.

At block 1306, the processor may obtain a maximum value of the coupling coefficient in response to varying, from an initial value to a final value, the one or more of the plurality of parameters of one of the plurality of groups (i.e., the set Group) while maintaining respective values of the one or more of the plurality of parameters of all other groups. For example, in a case where there are three groups as in the example of FIG. 5 (i.e., Group 1, Group 2, and Group 3) (i.e., N=3), the processor may obtain a maximum value of the coupling coefficient in response to varying, from an initial value to a final value, the one or more of the plurality of parameters of Group 1, (e.g., where Group 1 is the set Group for a first round, Group one is the “one of the plurality of groups” of the first round) while maintaining respective values of the one or more of the plurality of parameters of all other groups (e.g., Group 2 and Group 3). For example, the sequentially obtaining and storing circuitry 1043, as shown and described in connection with FIG. 10, may provide a means for obtaining a maximum value of the coupling coefficient in response to varying, from an initial value to a final value, the one or more of the plurality of parameters of one of the plurality of groups (i.e., the set Group) while maintaining respective values of the one or more of the plurality of parameters of all other groups.

In some examples, the processor may assign a respective range, a respective step size, and a respective starting value to each of the plurality of parameters. The varying from the initial value to the final value may then include varying, from the respective starting value to the final value, each of the plurality of parameters of the one of the plurality of groups (e.g., in the example where N=3, Group 1, Group 2, and Group 3) according to the respective range and the respective step size. In some examples, varying the one or more of the plurality of parameters may be performed according to a finite element analysis process.

At block 1308, the processor may store the maximum value of the coupling coefficient (obtained at block 1306) and the final value (also obtained at block 1306) of each of the one or more of the plurality of parameters associated with the one of the plurality of groups, where, in the present example, in the first round, the one of the plurality of groups is Group 1. For example, the sequentially obtaining and storing circuitry 1043 as shown and described in connection with FIG. 10 may provide a means for storing the maximum value of the coupling coefficient (obtained at block 1306) and the final value (also obtained at block 1306) of each of the one or more of the plurality of parameters associated with the one of the plurality of groups.

At block 1310, the processor may determine if there are any remaining groups. For example, the determining circuitry 1044, as shown and described in connection with FIG. 10, may provide a means for determining if there are any remaining groups. In the example of block 1310, the processor may determine if there are any remaining groups by comparing the current value of the counter, Group, to the number (N) of the plurality of groups defined in block 1302. That is, at block 1310, the processor may determine if Group=N. At block 1310, if Group does not equal N, then the process 1300 may advance to block 1312.

At block 1312, the counter (named Group in this example) may be incremented by one, i.e., Group=Group+1. For example, the communication and processing circuitry 1041, as shown and described in connection with FIG. 10, may provide a means for incrementing the counter by 1. Thereafter, the process 1200 may return to block 1306.

For the sake of providing a complete description of the process 1300, in an example where N=3, in the second round where Group=2, at block 1306, the processor, upon returning to block 1306, may obtain a maximum value of the coupling coefficient of the magnetic block in response to varying, from an initial value to a final value, the one or more of the plurality of parameters of Group 2, (e.g., where Group 2 is the set Group for the second round, Group 2 is the “one of the plurality of groups” of the second round) while maintaining respective values of the one or more of the plurality of parameters of all other groups (e.g., Group 1 and Group 3). Additionally, the process 1300, upon returning to block 1308, may store the maximum value of the coupling coefficient (i.e., a new maximum value obtained at block 1306 in the second round) and the final value (also obtained at block 1306) of each of the one or more of the plurality of parameters associated with Group 2, where Group 2 is the recited one of the plurality of groups in association with the second round.

Upon returning to block 1310 after the second round of obtaining and storing, the processor may determine if there are any remaining groups. That is, after the second round, at block 1310, the processor may determine if Group=N. Because Group=2 at the end of the second round, the processor would determine that Group does not equal N (e.g., where in this example N=3) and the process 1300 would again advance to block 1312, where Group would be incremented by one, so that Group=3.

For the sake of providing a complete description of the process 1300, in an example where N=3, in the third round, where Group=3, at block 1306, the processor, upon returning to block 1306, may obtain a maximum value of the coupling coefficient of the magnetic block in response to varying, from an initial value to a final value, the one or more of the plurality of parameters of Group 3, (e.g., where Group 3 is the set Group for the third round, Group 3 is the “one of the plurality of groups” of the third round) while maintaining respective values of the one or more of the plurality of parameters of all other groups (e.g., Group 1 and Group 2). Additionally, the process 1300, upon returning to block 1308, may store the maximum value of the coupling coefficient (i.e., a new maximum value obtained at block 1306 in the third round) and the final value (also obtained at block 1306) of each of the one or more of the plurality of parameters associated with Group 3, where Group 3 is the recited one of the plurality of groups in association with the third round.

Upon returning to block 1310 after the third round of obtaining and storing, the processor may determine if there are any remaining groups. That is, after the third round, at block 1310, the processor may determine if Group=N. Because Group=3 at the end of the third round, the processor would determine that Group does equal N (e.g., Group=3=N) and the process 1300 would advance to block 1314.

At block 1314, the processor may determine if a difference between the maximum value of the coupling coefficient of the magnetic block associated with the last group (in this example Group 3 (G3)) and the maximum value of the coupling coefficient of the magnetic block associated with the first group (in this example, Group 1 (G1)) is less than or equal to a predetermined number. In some examples, the predetermined number may be a predetermined percentage of the maximum value of the coupling coefficient associated with the first group.

If, at block 1314, the processor determines that the difference between the maximum value of the coupling coefficient of the magnetic block associated with the last group and the maximum value of the coupling coefficient of the magnetic block associated with the first group is not less than or equal to a predetermined number, then the process 1300 may advance to block 1316.

At block 1316, the processor uses the stored values of the coupling coefficient (i.e., the final value of the coupling coefficient obtained in the last round) and the stored values of the one or more of the plurality of parameters of each one of the plurality of groups (i.e., the stored/final values of the one or more of the plurality of parameters of associated with Group 1 in the first round, the stored/final values of the one or more of the plurality of parameters of associated with Group 2 in the second round, and the stored/final values of the one or more of the plurality of parameters of associated with Group 3 in the third round) as the initial values in the next repetition of blocks 1304-1314. The process then returns to block 1304.

However, returning to block 1314, if at block 1314 the process determines the difference between the maximum value of the coupling coefficient of the magnetic block associated with the last group and the maximum value of the coupling coefficient of the magnetic block associated with the first group is less than or equal to a predetermined number, then the process 1300 advances to block 1318.

At block 1318, the processor may drive machines (e.g., multi-axis end mills, shapers, presses, mixers, 3D printers, other computer aided manufacturing devices or apparatus) coupled to the processor (or another processor of a different apparatus) to manufacture the magnetic block according to the stored final values of each of the one or more of the plurality of parameters associated with the one of the plurality of groups.

For example, the determining circuitry 1044, as shown and described in connection with FIG. 10, may provide a means for determining if a difference between the maximum value associated with the last group and the maximum value associated with the first group is less than or equal to a predetermined number, and if not less than or equal to the predetermined number, return to the obtain, the store, and the repeat associated with the first group through and including the last group, and subsequently to the determine, or if less than or equal to the predetermined number, manufacture the magnetic block according to the stored final value of each of the one or more of the plurality of parameters associated with each of the first group through the last group.

Of course, in the above examples, the circuitry included in the processor 1004 of FIG. 10 is merely provided as an example. Other means for carrying out the described processes or functions may be included within various aspects of the present disclosure, including but not limited to the instructions stored in the computer-readable medium 1006 of FIG. 10 or any other suitable apparatus or means described in any one of the FIGS. 1, 2, 3, 4, 5, 7, 8, 9, 10, and/or 13 utilizing, for example, the processes and/or algorithms described herein in relation to FIGS. 5, 11, and/or 12.

Several aspects of magnetic block structures for enhanced coupling coefficients in wireless power transfer systems have been presented with reference to various exemplary implementations. As those skilled in the art will readily appreciate, various aspects described throughout this disclosure may be extended to other magnetic block structures and/or wireless power transfer systems.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B, and object B touches object C, then objects A and C may still be considered coupled to one another, even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features, and/or functions illustrated in FIGS. 1-13 may be rearranged and/or combined into a single component, step, feature, or function, or embodied in several components, steps, or functions. Additional elements, components, steps, and/or functions may also be added without departing from novel features disclosed herein. The apparatus, devices, and/or components illustrated in FIGS. 1-13 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The method claims present elements of the various steps in a sample order and are not meant to be limited to the specific order or hierarchy presented unless specifically recited therein. While some examples illustrated herein depict only time and frequency domains, additional domains, such as a spatial domain, are also contemplated in this disclosure.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language of the claims, wherein reference to an element in the singular is not intended to mean “one and only one” unless specifically so stated, but rather “one or more.” Unless specifically stated otherwise, the term “some” refers to one or more.

The word “obtain” as used herein may mean, for example, acquire, calculate, construct, derive, determine, receive, and/or retrieve. The preceding list is exemplary and not limiting. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public, regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

As used herein, the term “determine” or “determining” encompasses a wide variety of actions and, therefore, “determining” can include calculating, computing, processing, deriving, investigating, looking up (such as via looking up in a table, a database, or another data structure), inferring, ascertaining, measuring, and the like. Also, “determining” can include receiving (such as receiving information), accessing (such as accessing data stored in memory), transmitting (such as transmitting information), and the like. Also, “determining” can include resolving, selecting, obtaining, choosing, establishing, and other similar actions.

As used herein, a phrase referring to “at least one of” a list of items refers to any combination of those items, including single members. As an example, “at least one of: a, b, or c” is intended to cover: a, b, c, a-b, a-c, b-c, and a-b-c. As used herein, “or” is intended to be interpreted in the inclusive sense, unless otherwise explicitly indicated. For example, “a or b” may include a only, b only, or a combination of a and b. Similarly, a phrase referring to A and/or B may include A only, B only, or a combination of A and B.

As used herein, “based on” is intended to be interpreted in the inclusive sense, unless otherwise explicitly indicated. For example, “based on” may be used interchangeably with “based at least in part on,” “associated with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware, and software has been described generally, in terms of functionality, and illustrated in the various illustrative components, blocks, modules, circuits, and processes described above. Whether such functionality is implemented in hardware, firmware, or software depends upon the particular application and design constraints imposed on the overall system.

Various modifications to the examples described in this disclosure may be readily apparent to persons having ordinary skill in the art, and the generic principles defined herein may be applied to other examples without departing from the spirit or scope of this disclosure. Thus, the claims are not intended to be limited to the examples shown herein but are to be accorded the widest scope consistent with this disclosure, the principles, and the novel features disclosed herein.

Additionally, various features that are described in this specification in the context of separate examples can also be implemented in combination in a single implementation. Conversely, various features that are described in the context of a single implementation can also be implemented in multiple examples separately or in any suitable subcombination. As such, although features may be described above as acting in particular combinations, and even initially claimed as such, one or more features from a claimed combination can, in some cases, be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated into the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together in a single software product or packaged into multiple software products.

What is claimed is:

1. A method, comprising:
defining a plurality of groups including a first group through a last group, each of the plurality of groups including one or more of a plurality of parameters associated with a magnetic block, a coupling coefficient of the magnetic block being a function of the plurality of parameters, and each of the plurality of parameters included in only one of the plurality of groups;
obtaining a maximum value of the coupling coefficient in response to varying, from an initial value to a final value, the one or more of the plurality of parameters of one of the plurality of groups while maintaining respective values of the one or more of the plurality of parameters of all other groups;
storing the maximum value of the coupling coefficient and the final value of each of the one or more of the plurality of parameters associated with the one of the plurality of groups;
repeating, in a group-by-group sequence, the obtaining the maximum value and the storing the maximum value and the final value of each of the one or more of the plurality of parameters associated with the one of the plurality of groups for each of the plurality of groups including the first group through the last group; and
determining if a difference between the maximum value of the coupling coefficient associated with the last group and the maximum value of the coupling coefficient associated with the first group is less than or equal to a predetermined number, and
if not less than or equal to the predetermined number, returning to the obtaining, the storing, and the repeating associated with the first group through the last group, and subsequently to the determining, or
if less than or equal to the predetermined number, manufacturing the magnetic block according to the stored final value of each of the one or more of the plurality of parameters associated with each of the first group through the last group.

2. The method of claim 1, wherein the varying of the one or more of the plurality of parameters is performed according to a finite element analysis process.

3. The method of claim 1, wherein defining the plurality of groups comprises:
separating the plurality of parameters representative of a plurality of physical attributes of the magnetic block into the plurality of groups.

4. The method of claim 1, wherein the predetermined number is a predetermined percentage of the maximum value of the coupling coefficient associated with the first group.

5. The method of claim 1, further comprising:
assigning a respective range, a respective step size, and a respective starting value to each of the plurality of parameters.

6. The method of claim 5, wherein varying from the initial value to the final value further comprises:
varying, from the respective starting value to the final value, each of the plurality of parameters of the one of the plurality of groups according to the respective range and the respective step size.

7. The method of claim 1, wherein the plurality of parameters representative of a plurality of physical attributes of the magnetic block comprise at least one of: a groove width (GrooveWidth), a groove depth (GrooveDepth), a groove distance (GrooveDist), a groove corner inside radius (GrooveCornerInR), a groove corner outside radius (GrooveCornerOutR), a groove end corner radius (GrooveEndCornerR), or a groove end distance (GrooveEndDist).

8. The method of claim 1, wherein other parameters in addition to the plurality of parameters representative of a plurality of physical attributes of the magnetic block further comprise at least one of: self-inductance, coupling factor, or material volume.

9. An apparatus, comprising:
one or more memories; and
one or more processors being configured to, individually or collectively, based at least in part on information stored in the one or more memories:
define a plurality of groups including a first group through a last group, each of the plurality of groups including one or more of a plurality of parameters associated with a magnetic block, a coupling coefficient of the magnetic block being a function of the plurality of parameters, and each of the plurality of parameters included in only one of the plurality of groups;
obtain a maximum value of the coupling coefficient in response to varying, from an initial value to a final value, the one or more of the plurality of parameters of one of the plurality of groups while maintaining respective values of the one or more of the plurality of parameters of all other groups;
store the maximum value of the coupling coefficient and the final value of each of the one or more of the plurality of parameters associated with the one of the plurality of groups;
repeat, in a group-by-group sequence, the obtaining the maximum value and the storing the maximum value and the final value of each of the one or more of the plurality of parameters associated with the one of the plurality of groups for each of the plurality of groups including the first group through the last group; and
determine if a difference between the maximum value associated with the last group and the maximum value associated with the first group is less than or equal to a predetermined number, and
if not less than or equal to the predetermined number, return to the obtain, the store, and the repeat associated with the first group through and including the last group, and subsequently to the determine, or
if less than or equal to the predetermined number, manufacture the magnetic block according to the stored final value of each of the one or more of the plurality of parameters associated with each of the first group through the last group.

10. The apparatus of claim 9, wherein the one or more processors are further configured to vary the one or more of the plurality of parameters according to a finite element analysis process.

11. The apparatus of claim 9, wherein the one or more processors are further configured to define the plurality of groups by being configured to:
separate the plurality of parameters representative of a plurality of physical attributes of the magnetic block into the plurality of groups.

12. The apparatus of claim 9, wherein the predetermined number is a predetermined percentage of the maximum value associated with the first group.

13. The apparatus of claim 9, wherein the one or more processors are further configured to:
assign a respective range, a respective step size, and a respective starting value to each of the plurality of parameters.

14. The apparatus of claim 13, wherein to vary from the initial value to the final value the one or more processors are further configured to:
vary, from the respective starting value to the final value, each of the plurality of parameters of the one of the plurality of groups according to the respective range and the respective step size.

15. The apparatus of claim 9, wherein the plurality of parameters representative of a plurality of physical attributes of the magnetic block, comprise at least one of: a groove width (GrooveWidth), a groove depth (GrooveDepth), a groove distance (GrooveDist), a groove corner inside radius (GrooveCornerInR), a groove corner outside radius (GrooveCornerOutR), a groove end corner radius (GrooveEndCornerR), or a groove end distance (GrooveEndDist).

16. The apparatus of claim 9, wherein other parameters in addition to the plurality of parameters representative of a plurality of physical attributes of the magnetic block further comprise at least one of: self-inductance, coupling factor, or material volume.

17. An apparatus, comprising:
a pair of facing magnetic blocks;
a pair of grooves formed through facing surfaces of the pair of facing magnetic blocks, each of the pair of grooves having a groove width and a groove depth, each of the pair of grooves defining a perimeter of an island within outer borders of each of the pair of facing magnetic blocks, and
a pair of coils, each aligned with the pair of grooves, wherein a first permeability of a space within the pair of grooves is less than a second permeability of a body of a material that comprises the pair of facing magnetic blocks.

18. The apparatus of claim 17, further comprising:
a pair of groove fillers occupying the groove width and the groove depth of the pair of grooves, each of the pair of groove fillers having a respective one of the pair of coils coupled thereto.

19. The apparatus of claim 18, wherein a permeability of each of the pair of groove fillers is equal to that of air.

20. The apparatus of claim 17, wherein the groove width and the groove depth produce a final coupling coefficient that is greater than an initial coupling coefficient obtained with an initial groove width and an initial groove depth.
